(19) United States
(12) Patent Application Publication
(10) Pub. No.: US 2024/0379694 A1
(43) Pub. Date: Nov. 14, 2024

(54) SENSOR DESIGN

(71) Applicant: OBSIDIAN SENSORS, INC., San Diego, CA (US)

(72) Inventors: Heesun SHIN, San Diego, CA (US); Bing WEN, San Diego, CA (US); Edward CHAN, San Diego, CA (US); Sean ANDREWS, San Diego, CA (US); Tallis CHANG, San Diego, CA (US); John HONG, San Diego, CA (US)

(21) Appl. No.: 18/689,802

(22) PCT Filed: Sep. 7, 2022
(86) PCT No.: PCT/US2022/042779

§ 371 Date: Mar. 6, 2024

Related U.S. Application Data
(60) Provisional application No. 63/241,469, filed on Sep. 7, 2021.

(51) Int. Cl. H01L 27/146

(52) U.S. Cl. CPC H01L 27/14605; H01L 27/14609; H01L 27/14636; H01L 27/14649; H01L 27/14683

(57) ABSTRACT

Electronic devices comprising pixels for sensing, methods for operating the electronic devices, and methods for manufacturing the electronic devices are disclosed. In some embodiments, the electronic devices comprise hinges for supporting the pixels. In some embodiments, the electronic devices are configured to provide a bias voltage to the pixels.

### CROSS-REFERENCE TO RELATED APPLICATIONS

This application is a 371 application of PCT Application No. PCT/US2022/042779, filed on Sep. 7, 2022. The PCT application claimed the benefit of priority of U.S. Provisional Application No. 63/241,469, filed Sep. 7, 2021. The disclosures of the above-referenced applications are incorporated herein by reference.

### FIELD

This disclosure generally relates to sensor circuitry and structure.

### BACKGROUND

To reduce cost, it may be desirable to manufacture an electronic device by placing sensors on a glass substrate (e.g., to reduce cost per unit area of the electronic device, improve yield). There may be a difference between the manufacturing processes of the sensors and the glass substrate. For example, the sensors may be bolometers manufactured using a silicon process (following 0.25-0.35 μm lithography rules) while the glass substrate and its associated components may be manufactured following larger lithography rules (1.5 μm or larger). It may be more costly to manufacture interfacing components (e.g., hinges for supporting the sensors on the substrate) using the smaller sensor process.

When bias voltages are provided to the sensors, the bias voltage may reflect a condition of the electronic device. The accuracy of the bias voltage may be affected by noise. Additionally, the sensors may experience external forces. For example, the sensors may experience electrostatic forces caused by voltages applied (e.g., the bias voltage) between nodes of the sensor.

### BRIEF SUMMARY

Electronic devices comprising pixels for sensing, methods for operating the electronic devices, and methods for manufacturing the electronic devices are disclosed. In some embodiments, the electronic devices comprise hinges for supporting the pixels. In some embodiments, the electronic devices are configured to provide a bias voltage to the pixels.

In some embodiments, an electronic device, comprises a glass, two pixels comprising a pixel pitch, and a hinge between one of the two pixels and the substrate. The hinge supports the pixel, and a length of the hinge is greater than the pixel pitch.

In some embodiments, a method for manufacturing an electronic device comprises providing a substrate, providing a first pixel and a second pixel, providing a first hinge and a second hinge, coupling the first hinge and the second hinge to the substrate, coupling the first pixel to the first hinge, and coupling the second pixel to the second hinge. The coupled first pixel and the coupled second pixel are separated by a pixel pitch, a length of the first hinge is greater than the pixel pitch, and a length of the second hinge is greater than the pixel pitch.

In some embodiments, an electronic device comprises: an array of pixels comprising: a first pixel belonging to a first row of the array and a column of the array and a second pixel belonging to a second row of the array and the column of the array, a bias line electrically coupled to the first pixel and the second pixel, and a column line associated with the column of the array. And a method for operating the electronic device comprises: providing a first bias voltage, via the bias line, to the first pixel, electrically coupling the first pixel to the column line, electrically decoupling the first pixel from the column line, providing a second bias voltage, via the bias line, to the second pixel, electrically coupling the second pixel to the column line; and electrically decoupling the second pixel from the column line.

### BRIEF DESCRIPTION OF THE DRAWINGS

FIG. 1 illustrates an exemplary electronic device, according to embodiments of the disclosure.

FIG. 2 illustrates an exemplary electronic device, according to embodiments of the disclosure.

FIGS. 3A and 3B illustrate exemplary pixels, according to embodiments of the disclosure.

FIG. 4 illustrates an exemplary sensor circuit, according to embodiments of the disclosure.

FIG. 5 illustrates an exemplary sensor circuit, according to embodiments of the disclosure.

FIGS. 6A-6C illustrate exemplary pixels, according to embodiments of the disclosure.

FIG. 7A illustrates an exemplary pixel, according to embodiments of the disclosure.

FIG. 7B illustrates exemplary pixel characteristics, according to embodiments of the disclosure.

FIG. 8 illustrates an exemplary electronic device, according to embodiments of the disclosure.

FIG. 9 illustrates an exemplary pixel, according to embodiments of the disclosure.

FIGS. 10A-10D illustrate exemplary pixels, according to embodiments of the disclosure.

FIGS. 11A-11B illustrate an exemplary pixel, according to embodiments of the disclosure.

FIGS. 12A-12B illustrate exemplary pixels, according to embodiments of the disclosure.

FIG. 13 illustrates an exemplary method of manufacturing an electronic device, according to embodiments of the disclosure.

FIG. 14 illustrates an exemplary method of operating an electronic device, according to embodiments of the disclosure.

FIG. 15 illustrates a method of manufacturing an electromechanical system, according to embodiments of the disclosure.

FIG. 16 illustrates an exemplary sensor, according to embodiments of the disclosure.

### DETAILED DESCRIPTION OF EXEMPLARY EMBODIMENTS

In the following description of embodiments, reference is made to the accompanying drawings which form a part hereof, and in which it is shown by way of illustration specific embodiments which can be practiced. It is to be understood that other embodiments can be used, and structural changes can be made without departing from the scope of the disclosed embodiments.

To reduce cost, it may be desirable to manufacture an electronic device by placing sensors on a glass substrate (e.g., to reduce cost per unit area of the electronic device, improve yield). The examples described herein advantageously allow implementation of sensors on a glass substrate to meet electrical, thermal, and mechanical requirements of an associated electronic device. While the examples herein are primarily discussed in the context of glass substrates, it should be appreciated by those skilled in the art that other implementations could be used.

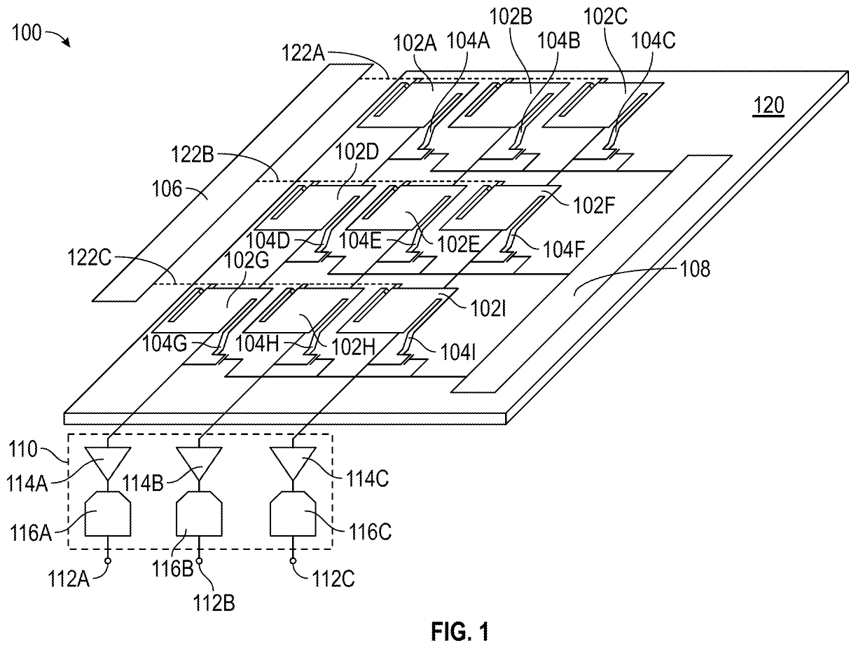

FIG. 1 illustrates an exemplary electronic device, according to embodiments of the disclosure. As illustrated, electronic device 100 comprises pixels 102A-102I, hinges 104A-104I, bias circuit 106, row circuit 108, readout circuit 110, outputs 112A-112C, and substrate 120.

In some embodiments, the electronic device 100 comprises a MEMS device, and the pixels 102A-102I comprise MEMS sensors. In some embodiments, the pixels 102A-102I comprise bolometers. In some embodiments, the bolometers are configured to sense long-wave infrared (LWIR) radiation. In some embodiments, the pixels 102A-1201 each comprise two nodes, and a resistance between the two nodes varies depending on radiation received by a pixel. Accordingly, when a voltage is applied across the two nodes of the pixel (e.g., between bias voltage and column line voltage), a current flows through the pixel, and the current is indicative of the pixel resistance (and hence, the radiation may be quantified (e.g., temperature)). In some embodiments, the hinges 104A-104I are configured to support a respective pixel 102A-102I. In some embodiments, as illustrated in FIG. 1, the pixels and hinges are arranged in a rectangular grid, and the pixels and hinges have a same pitch. That is, in some embodiments, adjacent pixels and adjacent hinges have same spacings.

In some embodiments, the pixels 102A-102I comprise an absorber (e.g., an absorbing layer) suspended above the substrate 120, and the hinges 104A-104I are configured to thermally isolate the pixels from the substrate. In some embodiments, the electronic device 100 comprises mirrors, each between a pixel and the substrate, and the hinges 104A-104I are configured to position the pixel at a position with respect to the mirror that increases absorption (e.g., increases absorption for LWIR radiation, quarter wavelength between absorber and mirror).

In some embodiments, the absorber comprises a resistive element having a high thermal coefficient of resistance (TCR) (e.g., such that the resistance of corresponding pixel scales with temperature, 1-5% per degree Celsius, following a relationship TCR=(1/R)(dR/dT)). In some embodiments, the absorber comprises metals, metal oxides, and metal oxynitrides, such as Ti, TiOxNy, V, MoCr, ITO. In some embodiments, a thickness of the absorber is designed such that the absorber's electromagnetic surface impedance matches that of free space (e.g., to increase absorption).

In some embodiments, the hinges 104A-104I comprise an electrically conductive component. In some embodiments, the pixels 102A-102I are electrically connected to a respective bias line (e.g., one of bias lines 122A-122C) and a corresponding pixel switch via the conductive hinges. In some embodiments, the thickness, length, width, and thermal conductance of the hinge affects sensitivity of a corresponding pixel, which may be expressed as noise-equivalent temperature difference (NETD). In some embodiments, if kth is the effective thermal conductivity of the hinge material (e.g., a single material, a composite of different materials (e.g., layered together)), the thermal conductance of a hinge is given by

$${G}_{th} = {k}_{th} \frac{WT}{L} \qquad ( 1 )$$

Examples of hinges are described in more detail herein.

In some embodiments, the bias circuit 106 is configured to provide a bias voltage to a respective row of pixels via a bias line (e.g., bias lines 122A-122C). For example, a row of pixels comprises pixels 102A, 102B, and 102C, and the row of pixels is electrically coupled to the bias line 122A. Examples of the bias circuit 106 are described herein.

In some embodiments, the row circuit 108 comprises a row multiplexing circuit. In some embodiments, the row multiplexing circuit is configured to select a row of pixels at each time to electrically couple the row of pixels to the readout circuit 110 (e.g., enabling signals generated by a row of pixels to be readout in a parallel fashion). In some embodiments, the row circuit 108 coordinates with the bias circuit 106, such that a bias voltage is provided to a row of pixels that are electrically coupled (by the row circuit) to the readout circuit.

In some embodiments, the readout circuit 110 comprises column readout circuit 114A-114C and analog-to-digital converters (ADC) 116A-116C. In some embodiments, each of the column readout circuit 114A-114C and each of the ADCs 116A-116C are electrically coupled to a respective column of pixels. For example, a column of pixels comprises pixels 102A, 102D, and 102G. In some embodiments, the column readout circuits 114A-114C are configured to receive signals from the columns. For example, a signal comprises a current generated based on a resistance of an electrically coupled pixel, a bias voltage at one node of the pixel, and a voltage at a second node of the pixel. In some embodiments, a column readout circuit comprises a capacitive trans-impedance amplifier (CTIA). In some embodiments, the ADCs 116A-116C are configured to receive outputs of column readout circuits 114A-114C and provide outputs 112A-112C, respective. In some embodiments, the outputs comprise digital representations of the signals received by the column readout circuits. In some embodiments, the readout circuit 110 comprises a readout integrated circuit (ROIC).

In some embodiments, the substrate 120 comprises a glass substrate. In some embodiments, the glass substrate comprises switches for coupling a pixel to a respective part of the readout circuit 110, and the switches are controlled by the row circuit 108. For example, the switches comprise thin-film transistors (TFT), and the row circuit is configured to provide a voltage for turning on a row of TFTs. When the row of TFTs turns on, a respective of row of pixels is electrically coupled to the readout circuit 110. In some embodiments, the switches comprise metal-oxide-semiconductor field-effect transistors (MOSFETs). In some embodiments, pixels 102A-102I, hinges 104A-104I, bias circuit 106, row circuit 108, and the switches are implemented on or over the substrate 120. In some embodiments, the substrate 120 is manufactured using a flat panel display process.

In some embodiments, because the substrate 120 is a glass substrate, metal layer thickness may be limited to 500 nm and a lower-resistance material (e.g., low-resistance copper) may not be available to reduce metal layer resistance. Therefore, column line resistance may be in a range of 1-100 kiloOhms. In some embodiments, the column voltage is held constant by the readout circuit 110 (e.g., using a CTIA), which measures a current flowing down the column line (from a selected pixel) instead of its voltage. By measuring the pixel current and holding the voltage constant, additional area and power consumption for implementing buffers to compensate for column line voltage drop may not be included, improving the performance of electronic device 100 on a glass substrate while reducing additional area and power cost.

In some embodiments, the readout circuit 110 is mounted on the glass substrate via a chip-on-glass (COG) process. In some embodiments, the readout circuit 110 is mounted on a flexible circuit, and the flexible circuit is attached to the glass substrate via a chip-on-flex (COF) process. The readout circuit 110, in some embodiments, generates 200-2000 mW of heat due to a number of signals being converted in parallel. The COF process may advantageously thermally isolate the readout circuit 110 from the glass substrate, reducing thermal stress gradients from a side of the electronic device 100 associated with the readout circuit. Furthermore, the COF process may allow a thicker conductive material (e.g., 1-10 μm) to electrically couple the readout circuit 110 to the electronic device 100, reducing voltage drops in a path to the readout circuit. In some embodiments, a metal plane is deposited on the substrate 120 (on a side opposite to the pixels) to reduce hotspot formation (from heat generated from the COF-attached readout circuit). In some embodiments, a metal layer (e.g., a metallized polymer) is inserted between the COF and the substrate 120 to further thermally decouple the readout circuit 110 from the substrate 120.

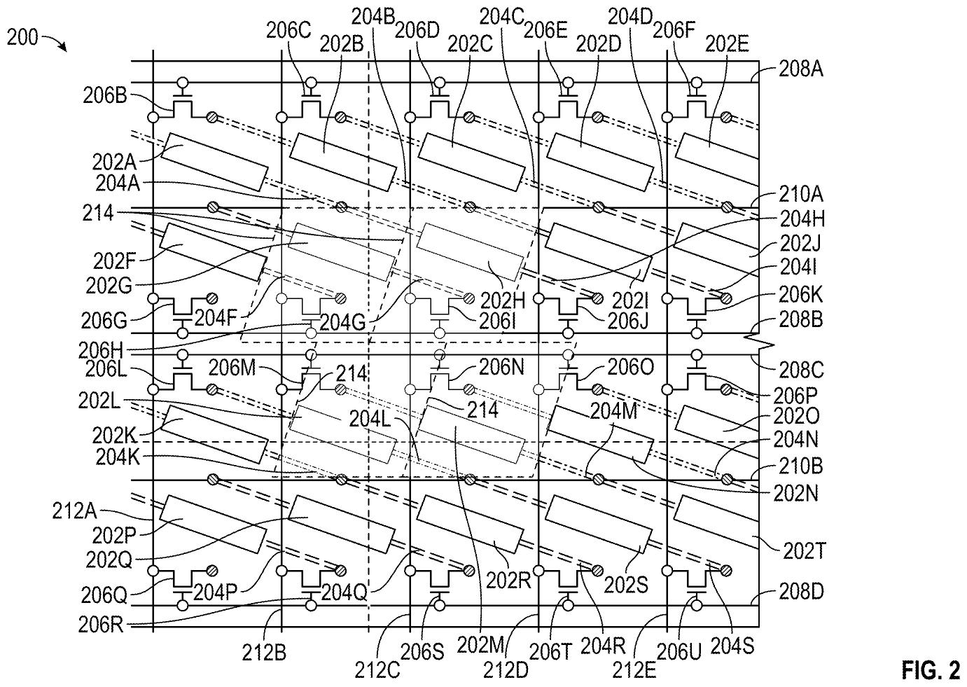

Although the electronic device 100 is described as illustrated in FIG. 1, it should be appreciated that the electronic device may be arranged and configured differently than illustrated. For example, the bias circuit and the row circuit may be placed at a different location of the device. As another example, the electronic device may comprise a different number of columns and a different number of row pixels. As another example, the readout circuit may comprise different components than described (e.g., the column readout circuit and the ADC may be integrated as one component). As another example, the pixels and hinges may be shaped, arranged, and sized differently than illustrated in FIG. 1. For instance, FIG. 2 illustrates another example of the electronic device.

It should also be appreciated that the components described with respect to FIG. 1 may be implemented with examples described with respect to the other Figures. For example, the bias circuit, row circuit, and readout circuit described with respect to FIG. 1 may be electrically coupled to electronic device 200, electronic device 300, or a pixel described with respect to the Figures. As another example, the pixels, hinges, and circuits described with respect to the other Figures may be implemented on electronic device 100.

FIG. 2 illustrates an exemplary electronic device 200, according to embodiments of the disclosure. In some embodiments, the electronic device 200 comprises pixels 202A-202T, hinges 204A-204T, switch 206A-206T, row lines 208A-208D, bias lines 210A-210B, and column lines 212A-212E. In some embodiments, the electronic device 200 comprises a substrate (e.g., substrate 120), and the components of FIG. 2 are disposed on the substrate. In some embodiments, the pixels 202A-202T comprise bolometer pixels.

In some embodiments, the pixels comprise a pixel pitch. For example, the pixel pitch is a distance between adjacent pixels (e.g., distance between same points (e.g., a same corner of the pixels) on neighboring pixels, distance between pixel 202A and 202B, distance between pixel 202A and 202F). As another example, the pixel pitch is a spatial periodicity (e.g., along a direction of the array) between pixels of a pixel array. In some embodiments, pixels 202A-202T are arranged in a non-rectangular manner. For example, relative to the row lines and column lines, the pixels are arranged diagonally. In some embodiments, the pixels comprise absorbers 214 (some hidden in FIG. 2 for clarity), and the absorbers are in parallelogram shapes, such that two edges of the absorber subtend an angle greater than 90 degrees. In some embodiments, a length of an edge of the absorber 214 is the pixel pitch.

In some embodiments, the hinges are between a respective pixel and a glass substrate. For example, hinge 204A is between the pixel 202A and the glass substrate. In some embodiments, the hinges support the respective pixels, and the lengths of the hinges (e.g., a distance between a node of the hinge electrically coupled to a bias line and a node of the hinge electrically coupled to a switch) are greater than the pixel pitch. For example, the hinge 204A supports the pixel 202A, and a length of the hinge 204A is greater than the pixel pitch. For example, the pixel pitch is 10-50 μm and the hinge length is 10-100 μm. In some embodiments, the hinges 204A-204T comprise a similar material as hinges 104A-104I.

In some embodiments, the hinges 202A-202T and the arrangements of the pixels and hinges advantageously reduce the cost of manufacturing electronic device 200. Because the hinges are greater than the pixel pitch, the hinges can be manufactured using a process of the glass substrate (e.g., a flat panel display process with 1.5 μm or higher lithography rules), which may be a cheaper process than a process of the pixels (e.g., a silicon process with 0.25-0.35 μ m lithography rules).

In some embodiments, the pixels 202A-202T and hinges 204A-204T are parts of a same mask layer. For example, the pixels and hinges are implemented using a one-sacrificial layer process. This may be advantageous in pixels greater than 40 μm in size or when large fill factors are possible for reducing a complexity and cost of the electronic device. In some embodiments, the pixels 202A-202T and hinges 204A-204T are each parts of different mask layers. For example, the pixels and hinges are implemented using a two-sacrificial layer process (e.g., separate layers for the hinges and pixels, a hinge layer comprising the hinges, a sensor-absorber layer comprising the pixels). This may be advantageous in pixels smaller than 40 μ m in size for creating a separate absorber structure in a pixel. Examples of the two-sacrificial layer process are described in more detail herein.

In some embodiments, a bias voltage is provided via a bias line (e.g., bias line 210A-210B from e.g., bias circuit 106). As illustrated, in some embodiments, two rows of pixels electrically couple to a bias line. For example, a row of pixels corresponding to row line 208A and a row of pixels corresponding to row line 208B are electrically coupled to the bias line 210A.

In some embodiments, electrically coupling the bias line to two rows of pixels advantageously reduces the cost of manufacturing electronic device 200. In some embodiments, electrically coupling the bias line to two rows of pixels allows the pixels to be arranged in a non-rectangular manner and the hinges to be greater than the pixel pitch. Because the hinges are greater than the pixel pitch, the hinges can be manufactured using a process of the glass substrate (e.g., a flat panel display process with 1.5 μ m or higher lithography rules), which may be a cheaper process than a manufacturing process of the pixels (e.g., a silicon process with 0.25-0.35 μ m lithography rules).

In some embodiments, the row lines 208A-208D are configured to conduct a signal (e.g., from row circuit 108) for controlling a respective row of switches 206A-206T (e.g., to turn on or turn off a row of switch). In some embodiments, the switches comprise TFTs, and the TFTs are part of a panel comprising the glass substrate. In some embodiments, the switches are configured to electrically couple the pixels to a respective column line. For example, in response to receiving a row signal on row line 208A to turn on a corresponding row of switches, the switch 206A is configured to electrically couple the pixel 202A to the column line 212A. In some embodiments, a current is generated based on voltage on a bias line, a resistance of a pixel (e.g., based on radiation received by the pixel), and a voltage of a column line. In some embodiments, the current flows to a readout circuit for measurement.

In some embodiments, one row of switches is turned on at one time. For example, one row of switches corresponding to 208A-208B is turned on at one time. In some embodiments, because a bias line is shared between two rows of pixels, a bias voltage is provided to the bias line while corresponding two rows of switches are turned on at different times, advantageously allowing bias voltage generation to not interfere with row switching in this bias line sharing configuration.

Although the electronic device 200 is described as illustrated in FIG. 2, it should be appreciated that the electronic device may be arranged and configured differently than illustrated. For example, the pixels may be arranged differently (e.g., different than the illustrated parallelogram absorber structure, hexagonal absorber structure). As another example, the hinges may be structured differently than illustrated. As another example, more than two rows of pixels may electrically couple to a bias line. As another example, the electronic device 200 may comprise a different number of pixels, hinges, switches, row lines, bias lines, and column lines than illustrated.

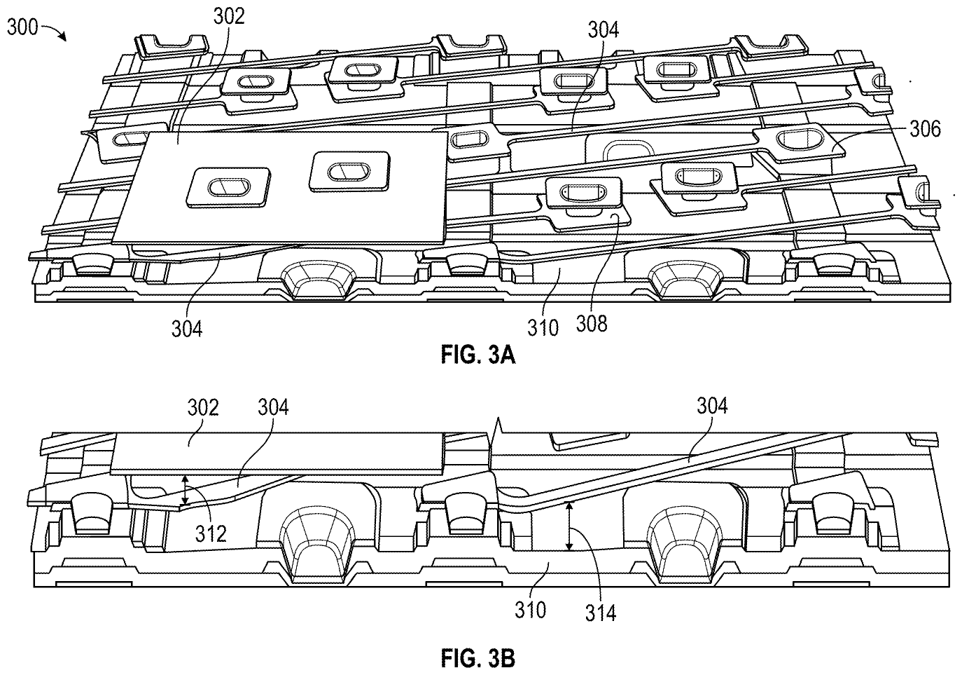

FIGS. 3A and 3B illustrate exemplary pixels, according to embodiments of the disclosure. For example, FIG. 3A illustrates a cross-section of an electronic device 300 created using a two-sacrificial layer process. In some embodiments, the electronic device 300 comprises pixels 302 (other pixels are not illustrated in FIGS. 3A and 3B for clarity), hinges 304, anchors 306, vias 308, and backplane 310. For example, one of the pixels 302 is one of pixels 102A-102I or 202A-202, and one of the hinges 304 is one of hinges 204A-204T.

In some embodiments, the anchors 306 fix ends of the hinges to the backplane 310. In some embodiments, the anchors comprise rivets for further stabilizing the hinges. In some embodiments, the vias 308 are configured to electrically couple the hinges to the circuitry of the backplane 310 (e.g., bias lines, row switches). In some embodiments, the backplane 310 comprises a TFT backplane and circuitry described with respect to FIGS. 1 and 2 (e.g., row lines, bias lines, switches). In some embodiments, the backplane 310 is disposed on a glass substrate.

In some embodiments, as illustrated in FIG. 3B, one of the pixels 302 is a distance 312 from one of the hinges 304. In some embodiments, the distance 312 is a distance from (1) a point of a pixel 302 facing the substrate to (2) a point of a hinge facing the surface of the pixel 302, and a line drawn between these two points is perpendicular to a surface the pixel 302. For example, the distance 312 is 500-2000 nm. In some embodiments, as illustrated in FIG. 3B, one of the hinges 304 is a distance 314 from the backplane 310. In some embodiments, the distance 314 is a distance from (1) a point of a hinge facing the substrate and a point of the substrate facing the hinge, and a line drawn between these two points is perpendicular to a surface of the substrate. For example, the distance 314 is 500-2000 nm.

Referring back to FIG. 2, in some embodiments, because pixels on two rows share a bias line, they may not be identical, but may have symmetry about the bias line. As a result, an electrical environment (e.g., voltage, current, noise) between alternating rows may be different (e.g., between pixels along row line 208A and pixels along row line 208B) due to lithography and process variations. In some embodiments, the difference can be reduced by generating a bias voltage specific to each row using a column of bias-generating pixels. For example, a bias voltage for a row of pixels is generated via one pixel of the column of bias-generating pixels. In some embodiments, the bias voltage generated for each row accounts for the lithography and process variations specific to a respective row. In some embodiments, the bias-generating pixels are shielded from incoming radiation (e.g., such that the bias voltage compensates for the lithography and process variations and ambient conditions without being affected by the incoming radiation).

In some embodiments, the bias-generating pixels have a same design as an active pixel (e.g., pixels 102A-102I, pixels 202A-202T). In some embodiments, the bias-generating pixels are part of an array of active pixels at an edge of the array, and to reduce edge effects on the bias-generating pixels, the bias-generating pixels are surrounded by dummy pixels (e.g., pixels not used for electronic device operation). For example, a column or a plurality of columns of dummy pixels surrounds the bias-generating pixels. The bias-generating pixels may also advantageously compensate for pixel resistance variations between rows due to process differences and thermal gradients.

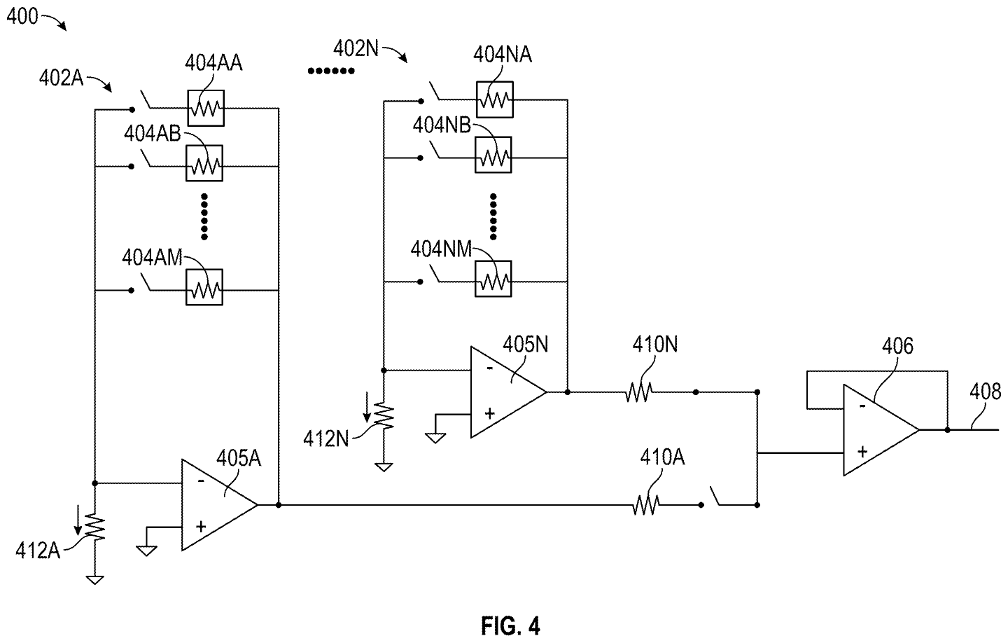

FIG. 4 illustrates an exemplary sensor circuit 400, according to embodiments of the disclosure. In some embodiments, the bias circuit 106 comprises parts of the sensor circuit 400 (e.g., the amplifiers, the buffer, input resistors, average resistors). In some instances, the bias-generating pixels experience flicker noise (e.g., 1/f noise) due to its size (e.g., same size as active pixels), and this noise may affect the accuracy of the generated bias voltage. The sensor circuit 400 advantageously reduces this noise.

In some embodiments, the sensor circuit 400 comprises a plurality of columns 402A-402N of bias-generating pixels, amplifiers 405A-405N, buffer 406, bias circuit output 408, averaging resistors 410A-410N, and resistors 412A-412N.

In some embodiments, each sensor of a column corresponds to a row of active pixels (such that e.g., lithography and process variations, self-heating of the bias-generating pixel are similar to those of a corresponding row of pixels). For example, pixel 404AA of column A (e.g., a first bias-generating pixel) and pixel 404NA of column N (e.g., a second bias-generating pixel) correspond to a first row of active pixels. Pixels 404AA and pixel 404NA are selected to electrically couple to the op amps 404A and 404N and to resistors 412A and 412N for generation of the bias voltage for the first row of active pixels. As another example, pixel 404AM of column A (e.g., a first bias-generating pixel) and pixel 404NM of column N (e.g., a second bias-generating pixel) correspond to a second row of active pixels. Pixels 404AM and pixel 404NN are selected to electrically couple to the op amps 405A and 405N and to resistors 412A and 412N for generation of the bias voltage for the second row of active pixels.

In some embodiments, the bias-generating pixels are scanned (e.g., one at a time) during calibration, and defective bias-generating pixels may not be used for generating a bias voltage.

In some embodiments, each of the columns is electrically coupled to an amplifier (e.g., amplifiers 405A-405N), providing a feedback path for the respective amplifiers. In some embodiments, the amplifier is an op amp. In some embodiments, resistors are electrically coupled to the inverting inputs of the amplifiers, and a voltage at an inverting input is generated based on a current through bias-generating sensor.

As an example, the bias voltage is generated as follows. During a first row time, first bias-generating pixels (e.g., pixels 404AA and 404NA) corresponding to a first row are electrically coupled (via switches) to respective resistors (e.g., resistors 412A and 412N) and respective amplifiers (e.g., amplifiers 404A and 404N). As a result, bias currents are generated through the bias-generating pixels and the resistors. The voltages at the output are based on a resistance of the bias-generating pixel. For example, the bias-generating pixel is a bolometer, and the resistance of the bias-generating sensor varies based on temperature (e.g., self-heating), lithography variation, and process variation. In some embodiments, the voltages at the output of the amplifiers 404A-404N are averaged at the input of the buffer 406, and the buffer 406 is configured to provide a bias voltage (e.g., the average of voltages at the output of the amplifiers). In some embodiments, the bias voltage is provided to a bias line of a disclosed electronic device. For example, the bias circuit output 408 is provided globally to an entire array of active pixels. As another example, the bias circuit output 408 is provided to one portion of the array at a time (e.g., one row at a time, a plurality of rows at a time). In some embodiments, the bias voltage at bias circuit output 408 is converted digitally (via an ADC, such as a same ADC as ADC 112A-112C), and the digital value of the bias voltage is used to adjust digital values of active sensor measurements (e.g., at outputs 112A-112C) for better accuracy.

In some embodiments, the average resistors 410A-410N are electrically coupled to a respective amplifier 404A-404N, and the resistances of the average resistors are the same. In some embodiments, one or more of the average resistors 410A-410N are electrically coupled to a respective column of bias-generating pixels to average the voltages generated by these columns. In some embodiments, the average resistors are configured to limit currents that can be driven back to the amplifiers if the voltages at the outputs of the amplifiers are different (e.g., they can prevent the outputs of the amplifiers from shorting).

By using more than one bias-generating sensors for one row and averaging a generated voltage between the bias-generating sensors, effects of bias-generating sensor noise and effects such as self-heating, lithography variation, and process variation may be reduced.

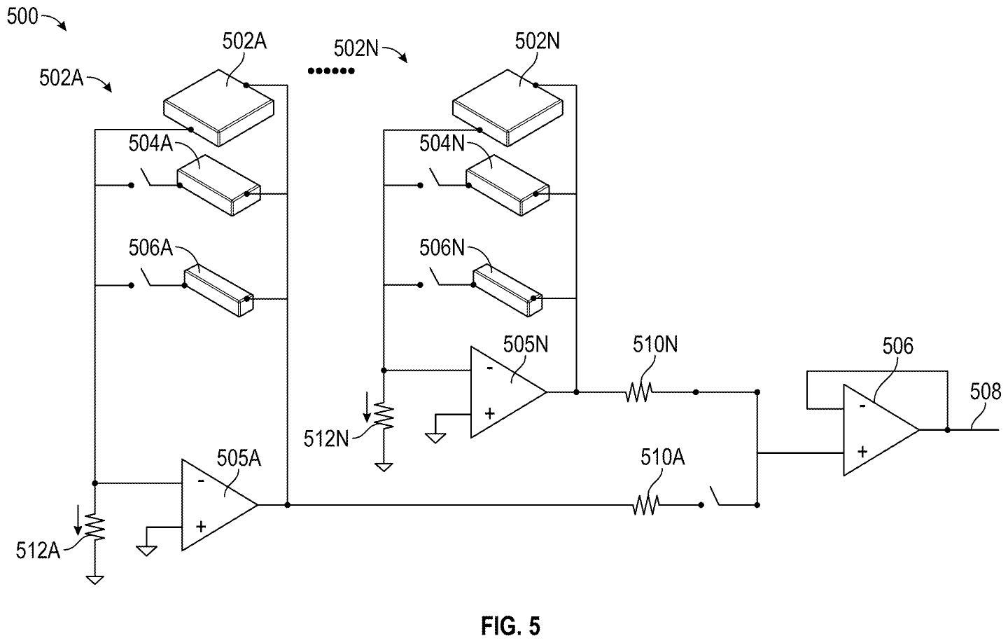

FIG. 5 illustrates an exemplary sensor circuit 500, according to embodiments of the disclosure. In some embodiments, the bias circuit 106 comprises parts of the sensor circuit 500 (e.g., the resistors, the buffer). In some instances, bias-generating pixels experience flicker noise (e.g., 1/f noise) due to its size (e.g., same size as active pixels), and this noise may affect the accuracy of the generated bias voltage. The circuit described with respect to FIG. 5 advantageously reduces this noise.

In some embodiments, the sensor circuit 500 comprises a plurality of bias-generating pixels (e.g., first bias-generating pixel 502A, second bias-generating pixel 504A, third bias-generating pixel 506A), amplifier 505A, buffer 506, bias circuit output 508, averaging resistor 510A, resistor 512A, and bias circuit output 508. In some embodiments, the sensor circuit 500 comprises a second plurality of bias-generating pixels (e.g., first bias-generating pixel 502N, second bias-generating pixel 504N, third bias-generating pixel 506N), a second amplifier 505N, a second averaging resistor 510N, and a second resistor 512N. It should be appreciated that the sensor circuit 500 may comprise a plurality of bias-generating pixels (e.g., bias-generating pixel 502A, 504A, 506A) or more than the first plurality of bias-generating pixels (e.g., bias-generating pixel 502A, 504A, 506A, 502N, 504N, 506N) and associate circuitries (e.g., for averaging voltages generated by multiple bias-generating pixels (e.g., pixels 502A, 502N)), as described with respect to FIG. 4). In some embodiments, the bias-generating pixels comprise bolometers.

In some embodiments, the bias-generating pixel 502A is electrically coupled to the amplifier 505A and resistor 512A, and the bias-generating pixels 504A and 506A are selectively electrically coupled parallel to the bias-generating pixel 502A via switches. In some embodiments, the bias-generating pixels 502N, 504N, and 506N are similarly electrically coupled. In some embodiments, the bias-generating pixels each comprise two electrodes (one for each node of a pixel) located at opposing sides of a pixel.

In some embodiments, the second bias-generating pixel (e.g., pixel 504A, 504N) and the third bias-generating pixel (e.g., pixel 506A, 506N) are selectively electrically coupled in parallel with the first bias-generating pixel to adjust an effective resistance of the bias-generating pixels and set a generated bias voltage to be in a desired range (e.g., dynamic range of amplifier). In some embodiments, the second and third bias-generating pixels are sized such that four different possible value of resistances may be achieved via switching these pixels. In some embodiments, a timing of switches electrically coupled to the second and third bias-generating pixels are modulated to mimic self-heating effects.

In some embodiments, a size of the first bias-generating pixel (e.g., bias-generating pixel 502A, bias-generating pixel 502N) is greater than a size of an active pixel (e.g., pixels 102A-102I, pixels 202A-202T). For example, the first bias-generating pixel has sufficient volume (e.g., an area of the first bias-generating pixel is 10-100 times greater than an area of an active pixel) to advantageously reduce flicker noise (e.g., 1/f noise). In some embodiments, the aspect ratio of the first bias-generating pixel is the same as the width-to-length ratio of an active sensor (e.g., to maintain a same resistance as the active pixel). In some embodiments, the first bias-generating pixel comprises same material as material of an active pixel. In some embodiments, the first bias-generating pixel comprises a thin film.

In some embodiments, the first bias-generating pixel is thermally coupled to a substrate (e.g., substrate 120, backplane 310). Thermally coupling to the substrate may advantageously allow the first bias-generating pixel to not be shielded from incoming radiation.

In some embodiments, each of the plurality of bias-generating pixels is electrically coupled to an amplifier (e.g., amplifiers 505A-505N), providing a feedback path for the respective amplifiers. In some embodiments, the amplifier is an op amp. In some embodiments, resistors (e.g., resistors 512A, 512N) are electrically coupled to the inverting inputs of the amplifiers, and a voltage at an inverting input is generated based on a current through bias-generating sensor (similar to FIG. 4).

In some embodiments, the bias voltage is provided to a bias line of a disclosed electronic device. For example, the bias circuit output 508 is provided globally to an entire array of active pixels. As another example, the bias circuit output 508 is provided to one portion of the array at a time (e.g., one row at a time, a plurality of rows at a time).

In some embodiments, a bias voltage generated by circuit 500 is measured. For example, to further remove effects of row-to-row variations due to variations in bias voltage, the bias voltage is measured and used to adjust active pixel measurements digitally. In some embodiments, a converter (e.g., an ADC comprising a CTIA, not shown, coupled to negative input of the amplifier) is used to measure a representation of the bias voltage (via a bias current through a resistor (not shown)), and this representation is converted into a digital value by the converter. It should be appreciated that the converter may electrically couple to a different part of the sensor circuit 500 for digitally converting a representation of the bias voltage.

This digital value of the bias voltage representation may be used to adjust digital representation of an active measurement (e.g., digital signals at outputs 112A-112C). In some embodiments, the converter comprises a same converter used for converting active pixel measurements (e.g., ADCs 116A-116C), advantageously reducing complexity of the electronic device's data conversion circuits. In some embodiments, the bias voltage representations of multiple bias-generating circuits are measured and averaged digitally via the converter to further adjust the digital measurements of the active pixels.

In some embodiments, additional pixels are used to generate the bias voltage and voltage at input of converter (e.g., to ensure the voltage at the converter input is within the converter's dynamic range). For example, as illustrated, second bias-generating pixel (e.g., bias-generating pixel 504A, bias-generating pixel 504N) and/or third bias-generating pixel (e.g., bias generating pixel 506A, bias-generating pixel 506N) may electrically couple (via switches) in parallel with a respective first bias-generating pixel to adjust the bias voltage and/or voltage at input of the converter. It should be appreciated that additional or less bias-generation pixels may be used for generating a bias voltage.

The following sections describe example structures of a disclosed electronic device (e.g., electronic device 100, electronic device 200, electronic device 300). In some embodiments, to span longer dimensions (e.g., longer than a pixel pitch), a hinge (e.g., hinges 204A-204T) may have an overall net tensile stress (e.g., greater than 100 MPa) over its operating temperature range, maintaining a flatness of the pixel, preventing movements due to electrostatic forces (e.g., caused by the bias voltage), and/or maintaining a sufficient mechanical resonance frequency (greater than 10 kHz) to reduce susceptibility to ambient vibrations. Additionally, the hinge may have a sufficiently low thermal conductivity (e.g., to thermally decouple the pixel from its surrounding and reduce effects of its surrounding on pixel reading) and a sufficiently high electrical conductivity (e.g., to electrically couple the pixel to circuitries).

In some embodiments, the hinge design is based on pixel resistance, such that the pixel resistance dominates a total resistance of a sensor readout path (e.g., a series resistance of pixel resistance, hinge resistances, switch resistance, and column resistance) and a voltage drop across the pixel is the highest across any components in the sensor readout path (for more precise pixel measurement, improved readout signal dynamic range, and improved signal-to-noise ratio). In some embodiments, the switch resistance is 10-100 kiloOhm. For example, the switch comprises a TFT switch sized based on LWIR sensor pixel pitch (e.g., 10-50 μ m) and manufactured in LTPS and IGZO technologies. In some embodiments, the TFT comprises amorphous silicon. In some embodiments, the switch resistance is 1 megaOhm. In some embodiments, the hinge resistance is in a same range as the switch resistance. In some embodiments, variability of switch resistance may add noise to sensor measurement, and it is limited to LSB of the pixel, which for example, is 0.1-1% of the switch resistance. Thus, in some embodiments, the pixel resistance is 100 kiloOhm to 10 megaOhm for achieving 10-12 bit resolution. In some embodiments, to have a resistance of 100 kiloOhm or below, the hinge comprise a material having a resistivity of less than 16 milliOhm-cm.

In some embodiments, to have a sufficiently low thermal conductivity (<50 nW/K), the hinge may be longer and have a smaller cross section according to equation (1). As an example, a hinge comprising a material having a thermal conductivity of 3 W/mK and having dimensions of W=1 μm, T=100 nm, and L=30 μm provides a thermal conductivity of 20 nW/K. In some embodiments, as a result of the hinge geometry (e.g., a length to width ratio of 30:1, a length to thickness ratio of 300:1, a length to width ratio above a threshold ratio for meeting electrical and thermal conductivities requirements, a length to thickness ratio above a threshold ratio for meeting electrical and thermal conductivities requirements), curling caused by stress gradients may advantageously be reduced, unlike some other serpentine hinge designs.

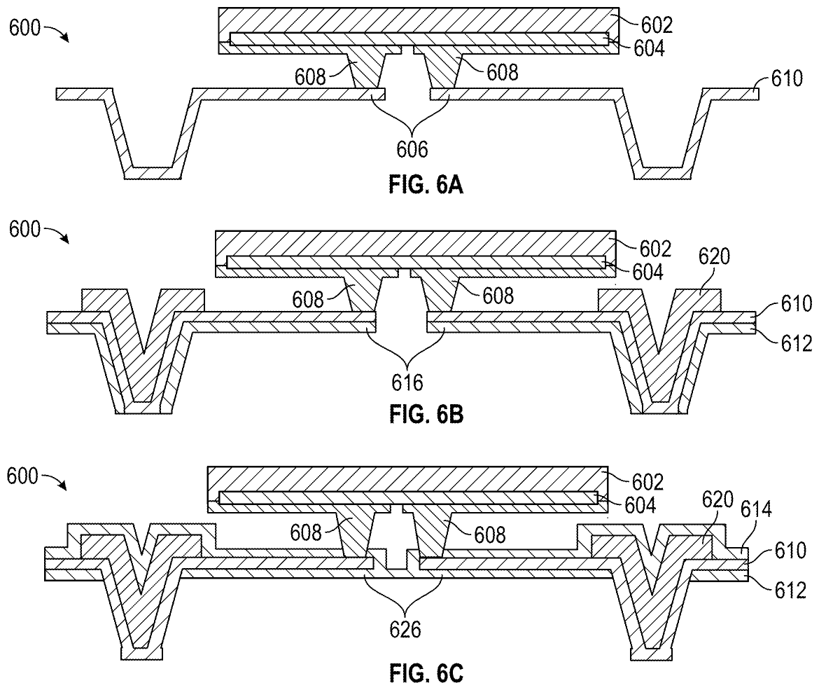

FIGS. 6A-6C illustrate exemplary pixels, according to embodiments of the disclosure. The hinges described with respect to these figures may advantageously satisfy the above requirements (e.g., allowing a hinge to be longer than a pixel pitch and achieving the benefits described herein). In some embodiments, the example hinges comprise one or more layers to meet or exceed electrical, thermal, and mechanical requirements (e.g., for electronic device 100, electronic device 200, electronic device 300).

In some embodiments, as illustrated in FIG. 6A, the pixel 600 comprises a sensor 602 and electrical insulator 604. The pixel 600 is electrically coupled to the hinge 606 through vias 608. In some embodiments, the hinge 606 is a hinge described with respect to FIGS. 1-3B. In some embodiments, the vias 608 are vias 308. In some embodiments, the hinge 606 comprises a TiNx layer 610.

In some embodiments, as illustrated in FIG. 6B, the pixel 600 comprises a sensor 602 and electrical insulator 604. The pixel 600 is electrically coupled to the hinge 616 through vias 608. In some embodiments, the hinge 616 is a hinge described with respect to FIGS. 1-3B. In some embodiments, the vias 608 are vias 308. In some embodiments, the hinge 616 comprises a TiNx layer 610 and a SiNx layer 612 below the TiNx layer. The SiNx layer may advantageously balance stresses (on the hinge) and protect the TiNx layer from oxidation.

In some embodiments, the SiNx layer is designed to provide tensile stress while allowing the TiNx layer to increase electrical and thermal conductivity. In some embodiments, the TiNx layer is designed (e.g., a length to width ratio of 30:1, a length to thickness ratio of 300:1, a length to width ratio above a threshold ratio for meeting electrical and thermal conductivities requirements, a length to thickness ratio above a threshold ratio for meeting electrical and thermal conductivities requirements to meet electrical and thermal requirements, and the SiNx layer is designed to satisfy mechanical requirements. In some embodiments, the thermal conductivity of the TiNx is reduced in cubic phase of the TiNx material while having electrical conductivity of 1-10 milliOhm-cm.

In some embodiments, a rivet 620 is placed at an anchor (e.g., anchor 306) of the hinge for reinforcing the hinge. The rivet 620 may advantageously provide reinforcement for the hinge and allow the vias and pixel to be further supported at a height (e.g., 500-2000 nm between a pixel and substrate) for increasing radiation absorption while keeping thermal conductivity lower by maintaining lower hinge thickness and/or width. In some embodiments, the rivet 620 is placed above the TiNx layer 610 (as illustrated). In some embodiments, the rivet is placed below the TiNx layer. In some embodiments, the rivet 620 comprises a sputtered metal such as Molybdenum, which may advantageously have wet etch selectivity over TiNx. It should be appreciated that the rivet placed at an anchor may have a different structure than illustrated. It should be appreciated a component other a rivet may be placed at an anchor to reinforce the hinge.

In some embodiments, as illustrated in FIG. 6C, the pixel 600 comprises a sensor 602 and electrical insulator 604. The pixel 600 is electrically coupled to the hinge 626 through vias 608. In some embodiments, the hinge 626 is a hinge described with respect to FIGS. 1-3B. In some embodiments, the vias 608 are vias 308. In some embodiments, the hinge 626 comprises a TiNx layer 610, a first SiNx layer 612 below the TiNx layer, and a second SiNx layer 614 above the TiNx layer (and above the rivet 620). The first and second SiNx layers may advantageously balance stresses (on the hinge) and protect the TiNx layer from oxidation.

In some embodiments, the SiNx layers are designed to provide tensile stress while allowing the TiNx layer to increase electrical and thermal conductivity. In some embodiments, the TiNx layer is designed (e.g., a length to width ratio of 30:1, a length to thickness ratio of 300:1, a length to width ratio above a threshold ratio for meeting electrical and thermal conductivities requirements, a length to thickness ratio above a threshold ratio for meeting electrical and thermal conductivities requirements, and the SiNx layers are designed to satisfy mechanical requirements. In some embodiments, the thermal conductivity of the TiNx is reduced in cubic phase of the TiNx material while having electrical conductivity of 1-10 milliOhm-cm.

In some embodiments, a rivet 620 is placed at an anchor (e.g., anchor 306) of the hinge for reinforcing the hinge. The rivet 620 may advantageously provide reinforcement for the hinge and allow the vias and pixel to be more supported at a height (e.g., 500-2000 nm between a pixel and substrate) for increasing radiation absorption while keeping thermal conductivity lower by maintaining lower hinge thickness and/or width. In some embodiments, the rivet 620 is placed above the TiNx layer 610 (as illustrated). In some embodiments, the rivet is placed below the TiNx layer. In some embodiments, the rivet 620 comprises a sputtered metal such as Molybdenum, which may advantageously have wet etch selectivity over TiNx. It should be appreciated that the rivet placed at an anchor may have a different structure than illustrated. It should be appreciated a component other a rivet may be placed at an anchor to reinforce the hinge.

In some embodiments, the hinges are processed as flatly as possible, such that when an associated electronic device is released and suspended, rubber band tension may keep the hinge and attached pixel flat and reduce twisting. For example, the topography under a first sacrificial layer may create uneven levels that may cause a surface of the hinge not be planar. This may cause the hinge to have nonuniformities e.g., in thickness, width, and stress.

In some embodiments, the bottom of the vias are placed near a center of the pixel to increase a length of the hinges and maintain rubber band action between anchors. In some embodiments, contacts between the top of the vias and the pixel are increased to utilize the full volume of the pixel. In some embodiments, the vias (each corresponding to nodes of the pixel) are designed to reduce resistance and noise. In some embodiments, the SiNx layers described with respect to FIGS. 6B and 6C span continuously between two anchors for maintaining this rubber band tension.

Although the hinges of FIGS. 6A-6C are described as having specific material, it should be appreciated that the hinges may comprise different material for meeting the electrical, thermal, and mechanical requirements. For example, the hinges may comprise CrN, ZrN, ITO, IZO, TiOx, and/or other conductive metal oxides and nitrides.

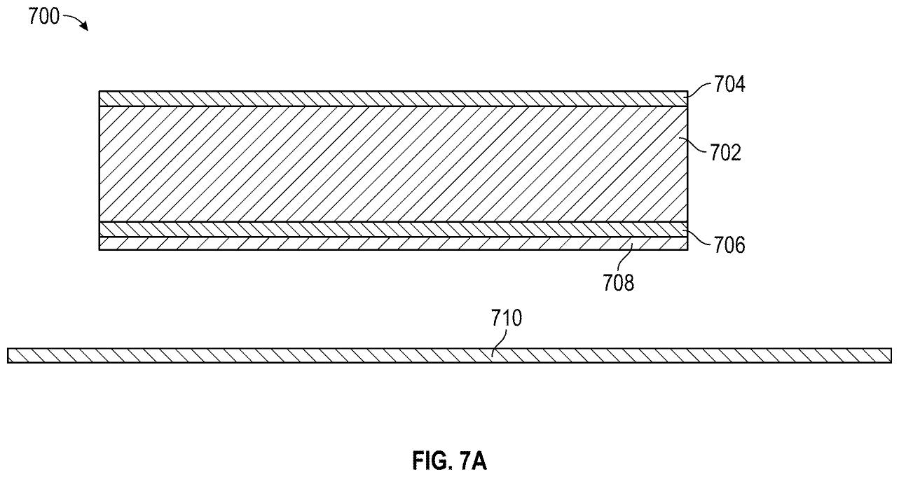

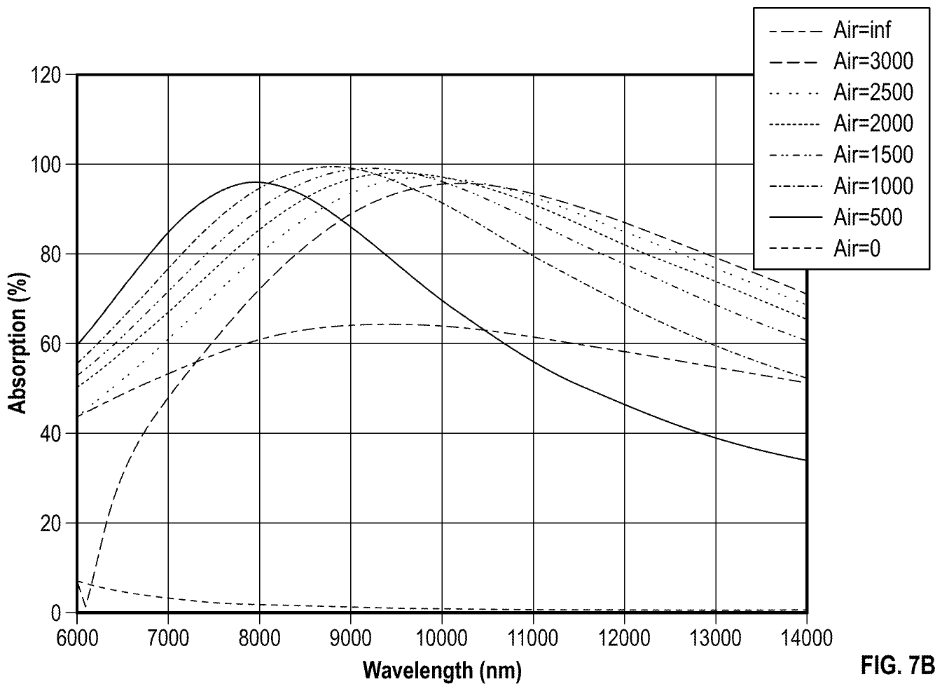

FIG. 7A illustrates exemplary pixel layers, according to embodiments of the disclosure. As discussed above, in some embodiments, pixel resistance dominates a total resistance of a readout path to increase signal dynamic range and improve readout sensitivity. In some embodiments, the pixel resistance is in range between 100 kiloOhm and 10 megaOhm. To achieve this resistance, in some embodiments, the pixel 700 (e.g., pixels 102A-102I, 202A-202T, pixels 302, pixel 600) comprises a sensor 702, which comprises doped amorphous silicon (e.g., N-type amorphous silicon, P-type amorphous silicon) having resistivity in a range of 50-500 Ohm-cm. In some embodiments, the sensor 702 comprises N-type amorphous silicon, which may have a higher temperature coefficient of resistance (TCR) than P-type amorphous silicon for a given resistivity and may maintain its operational properties up to 110 degrees Celsius. In some embodiments, the sensor 702 comprises ZrOx and/or TiOx. In some embodiments, the pixel 700 comprises a bolometer.

In some embodiments, the sensor 702 has a thickness of 50-500 nm. The sensor thickness may advantageously reduce delamination and cracking in glass-based fabrication process. Furthermore, the sensor thickness may reduce the pixel's thermal capacity and allow the pixels to be readout at 9-60 frames per second.

In some embodiments, the pixel 700 comprises insulating layers 704 and 706. In some embodiments, the insulating layers 704 and 706 comprise a material with a low density of traps, such as silicon-rich SiNx or undoped amorphous silicon. In some embodiments, a thickness of the insulating layer 704 or insulating layer 706 is 20-50 nm, which may prevent surface traps from producing noise fluctuations. In some embodiments, the insulating layers advantageously protect the sensor 702 from oxygen radicals (e.g., during release etch prior to vacuum encapsulation, which may be performed prior to device singulation).

In some embodiments, the pixel 700 comprises an absorber 708. In some embodiments, the absorber 708 is configured to absorb LWIR radiation (e.g., absorption in 8-12 μ m). In some embodiments, the absorber 708 comprises a conductive contact layer under the sensor 702. In some embodiments, the conductive contact layer is configured for bias control of the semiconductive properties of the sensor 702. In some embodiments, the absorber 708 comprises titanium and/or titanium-rich TiNx. In some embodiments, the absorber 708 comprises TiOxNy, V, MoCr, CrN, ITO, or any combination thereof.

In some embodiments, fabricating the pixel 700 comprises performing a dry release process such as oxygen ashing and XeF₂ (e.g., to prevent stiction in surface micromachining processes). In some embodiments, fabricating the pixel 700 comprises oxygen ashing of an organic sacrificial layer.

In some embodiments, the absorber 708 is on the bottom of the pixel 700, as illustrated. This may result in asymmetry that can cause curling due to stress gradients. To reduce curling, the stiffness of the pixel may be increased. For example, to increase pixel stiffness, the pixel is corrugated by etching grooves (e.g., 50-300 nm deep) in the insulating layer 704 before forming the pixel stack. In some embodiments, the grooves are in directions susceptible to curling (e.g., diagonal directions).

In some embodiments, the pixel 700 is placed above a mirror 710, as illustrated. In some embodiments, the mirror 710 is part of a backplane (e.g., a TFT backplane) and/or a substrate (e.g., glass substrate). In some embodiments, incoming radiation enters from the top of the pixel, through the sensor 702, and to the absorber 708. Some of the incoming radiation may be absorbed by the absorber at this point. The remaining unabsorbed radiation traverses the absorber and reaches the mirror 710. The remaining radiation reflects back to the absorber 708, and the absorber 708 absorbs at least some of the reflected radiation. In some embodiments, a distance between the pixel 700 and mirror 710 is a quarter wavelength of a radiation wavelength of interest (e.g., to form a quarter-wave cavity for increased absorption).

In some embodiments, the absorber 708 has a topography in the range of 50-1000 nm due to e.g., topography of the backplane (e.g., from deep vias), topography of the substrate, reduced planarization from an organic sacrificial layer due to a shrinkage and deposition process, absorber curling due to stress. Furthermore, in some embodiments, in a two-sacrificial layer design (e.g., electronic device 300), the hinges between pixel and mirror layer may affect optical response of a quarter-wave cavity formed between the pixel and the mirror. That is, the topography and the hinges may affect an amount of absorption due to a varying distance between the pixel and the mirror. For example, due to these effects, a quarter-wave distance between the pixel and the mirror may not be maintained.

In some embodiments, the absorber 708 comprises Ti and has a thickness of 5-20 nm. In some embodiments, the absorber 708 comprises TiNx and has a thickness of 20-100 nm. In some embodiments, the sensor 702 and absorber 708 are designed to advantageously increase absorption of radiation in the LWIR band while a distance between the pixel 700 and mirror 710 varies (due to the reasons described above). For example, the distance between the absorber 708 and mirror 710 varies between 500-3000 nm.

In some embodiments, the pixel 700 may advantageously allow more LWIR radiation to be absorbed while a distance between the pixel 700 and mirror 710 varies, reducing a step to planarize the mirror surface via more costly processes such as chemical mechanical polishing (CMP). Furthermore, such planarization processes may not allow the use of rivets for reinforcing the hinges because they would require a high fill factor.

FIG. 7B illustrates exemplary pixel characteristics, according to embodiments of the disclosure. In some embodiments, FIG. 7B illustrates characteristics of pixel 700 and the advantages of the pixel design described above. As shown in the plot, the pixel 700 is configured to absorb at least 60% of waves of incoming radiation having wavelengths 8000-12000 nm for gaps between 500-3000 nm (the varying distance between the absorber and mirror). For example, for every 100 waves, the absorber is configured to detect at least 60 of them, and the waves are between 8000 and 12000 nm. As shown in the plot, the pixel 700 is configured for absorb at least 35% of waves of incoming radiation having wavelengths 6000-14000 nm for gaps between 500-3000 nm. For example, for every 100 waves, the absorber is configured to detect at least 35 of them, and the waves are between 6000 and 14000 nm.

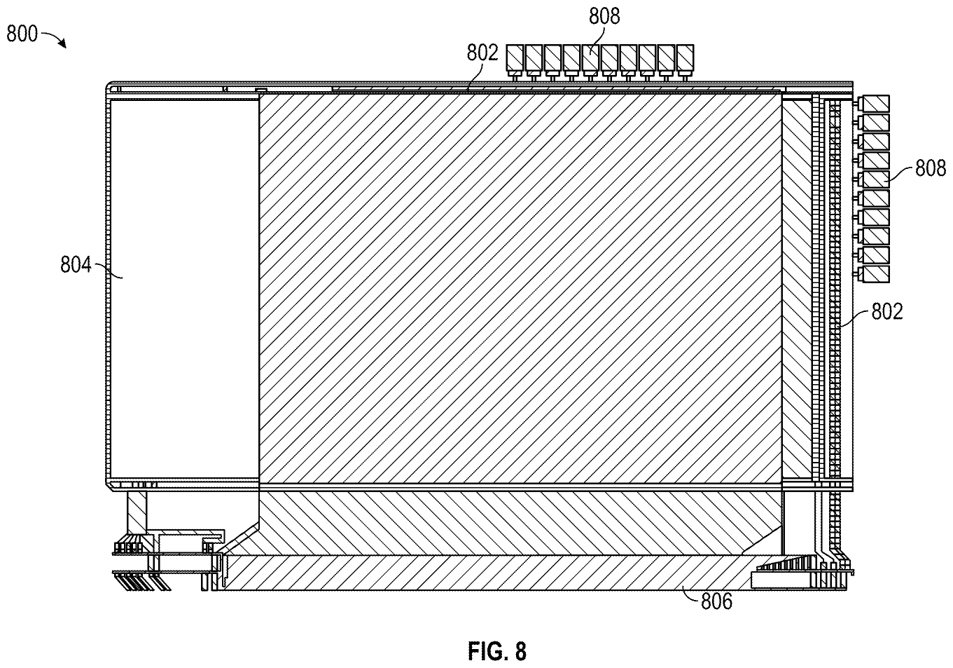

FIG. 8 illustrates an exemplary electronic device 800, according to embodiments of the disclosure. In some embodiments, the electronic device 800 comprises a disclosed electronic device (e.g., electronic device 100, electronic device 200, electronic device 300). In some embodiments the electronic device 800 comprises a multiplexer 802. In some embodiments, the multiplexer 802 is located away from row circuit 804 or readout circuit 806 (e.g., on a side of the electronic device not associated with the row circuit or readout circuit). In some embodiments, the multiplexer 802 is configured to electrically couple the electronic device 800 to testing circuit 808. For example, the testing circuit 808 comprises test pads (e.g., pogo pin pads) for an automatic wafer prober. The multiplexer 802 may advantageously allow testing of the pixel array of the electronic device 800 (e.g., for quality control) while a plurality of electronic devices is on a glass panel, prior to subsequent dicing and assembly steps. In some embodiments, after the electronic device 800 is separated from other devices on the panel, the multiplexer 802 may be deactivated (e.g., by shorting gates, inputs, and/or outputs of the multiplexer to a fixed voltage).

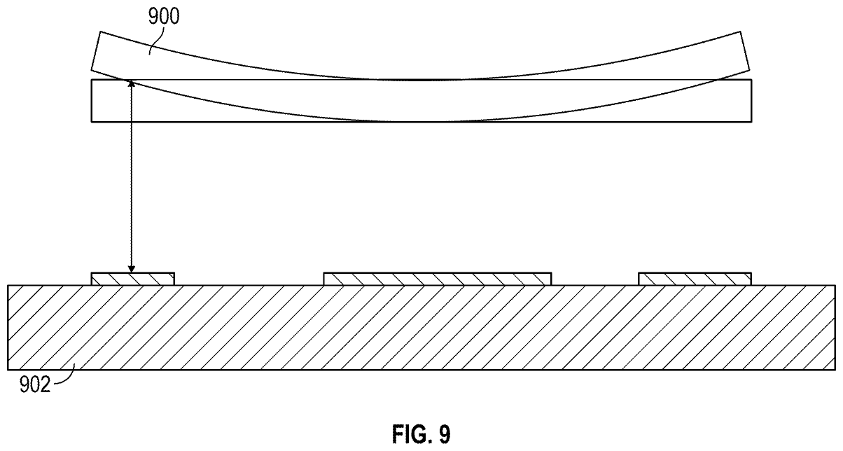

In some embodiments, the disclosed pixels comprise bolometers. In some instances, because the microbolometer may operate over a large range of ambient temperatures, the biasing voltage may have to adapt to the changing conditions. For semiconducting pixels, for example, the coefficient of resistance is negative, typically in the range of −2 to −3% per degree Kelvin. If a bolometer with a nominal pixel resistance of 1 megaOhm at room temperature (25 degrees Celsius) is subjected to an ambient temperature that ranges from −40 to 80 C, often a requirement for automotive and other demanding applications, the pixel resistance would vary from about 5.3 megaOhms to 395 kiloOhms. This assumes a single activation energy for the resistive material, such as amorphous silicon, silicon germanium, and various metal oxides. Given a hinge design and given also the range of voltage differences that may exist between portions of the suspended pixel, stability problems involving piston or rotational (tipping) pull-in of the suspended pixel responding to local electrostatic forces. These stability problems may cause unstable tilting that can result in corners or edges of the pixel becoming stuck to the substrate which disables pixel operation due to thermal shunting. FIGS. 9-12B describe examples for reducing effects of electrostatic forces. It should be appreciated that examples of structures for reducing effects of electrostatic forces may be implemented in a disclosed electronic device (e.g., electronic device 100, electronic device 200, electronic device 300, electronic device 800).

FIG. 9 illustrates an exemplary pixel 900, according to embodiments of the disclosure. In some embodiments, a shape of the pixel 900 of convex. That is, the induce convex curvature causes an increase in the gap between the pixel and a layer below (e.g., substrate 902, lower levels of metal below it) at edges of the pixel 900. For example, as illustrated, the pixel 900 has convex shape, relative to the substrate 902. In some embodiments, the pixel 900 comprises a layer of silicon nitride that having high in-plane stress is applied to induce the convex curvature. The induced convex curvature may advantageously reduce maximum electrostatic torque near the corners or edges of the pixel. In some embodiments, the shape of pixel 900 is symmetrical (e.g., the convexity of the pixel is symmetrical such that distances between a point of the pixel and the substrate about an axis of symmetry are the same). In some embodiments, the shape of pixel 900 is non-symmetrical (e.g., the convexity of the pixel is non-symmetrical).

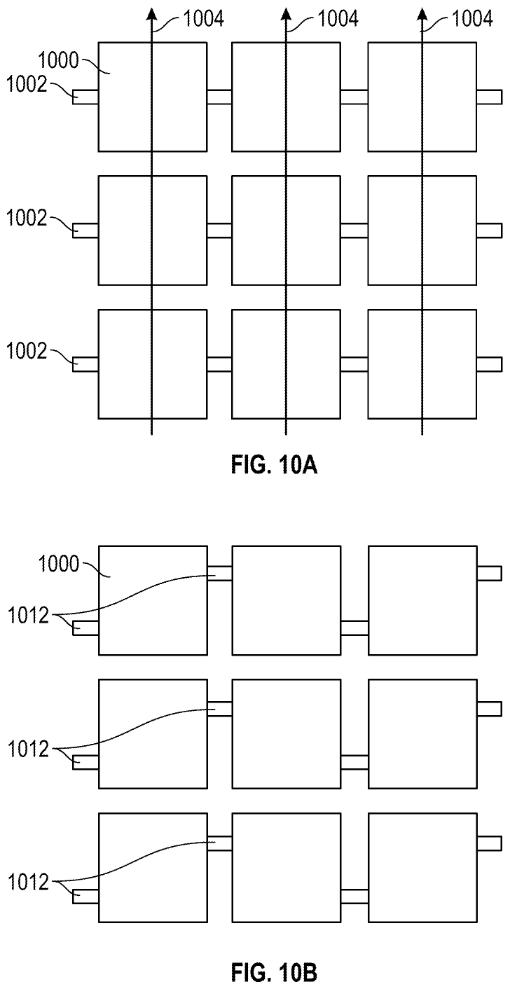

FIGS. 10A-10D illustrate exemplary pixels 1000, according to embodiments of the disclosure. In some embodiments, an electronic device comprises a bridge supporting the pixels 1000. In some embodiments, the bridge is configured to support a pixel and its neighbor, as illustrated in FIGS. 10A-10D. The bridge may advantageously prevent movement of the pixels about an axis of rotation (e.g., axis of rotation 1004) (e.g., caused by electrostatic forces) by locating the bridges at points of increased leverage about the axis of rotation. Additionally, the bridges may advantageously reduce oscillations (e.g., caused by high vacuum environment of the pixels and bias pulses (e.g., bias voltage that is provided periodically at each row time)) by dispersing mechanical energy to neighboring pixels more quickly. It should be appreciated that the bridges illustrated in FIGS. 10A-10D are exemplary. The bridges may be arranged differently than illustrated. For example, the bridge may support different pixels at different corresponding points of a respective pixel, compared to a same corresponding point of some pixels (e.g., compared to a bridge supporting a center of pixels, compared to a bridge supporting a same side of pixels).

In some embodiments, the bridge comprises insulating material with cross sections (e.g., smaller relative to area of the pixel) to reduce thermal cross talk between pixels in proximity to each other. For example, the bridge comprises a thin film. In some embodiments, the smaller cross sections have in-plane stress due to a fabrication process, and the stress provides stiffness to prevent pixel movement due to electrostatic forces. In some embodiments, the bridge couples to a hinge associated with the pixel. In some embodiments, the bridge couples to the pixel. In some embodiments, an additional sacrificial spacer layer (e.g., a third layer above the pixel) above the pixel is added, and the additional layer creates a third dimension and elongates the bridge. The additional spacing (created by the additional layer) may advantageously reduce thermal cross talk.

For example, as illustrated in FIG. 10A, bridges 1002 are arranged along a center of the pixels in a direction perpendicular to axes of rotation 1004. As another example, as illustrated in FIG. 10B, bridges 1012 are arranged along alternating sides of the pixels in a direction perpendicular to axes of rotation 1004. As another example, as illustrated in FIG. 10C, bridges 1022 are arranged along two sides of the pixels (e.g., with portions of two bridges supporting a pixel) in a direction perpendicular to axes of rotation 1004. As another example, as illustrated in FIG. 10D, bridges 1032 are arranged along centers of the pixels in directions perpendicular and parallel to axes of rotation 1004.

It should be appreciated that depending on an electronic device's mechanical requirements and the pixels and hinges' ability to withstand electrostatic forces, more or less bridges than described may be added to support the pixels.

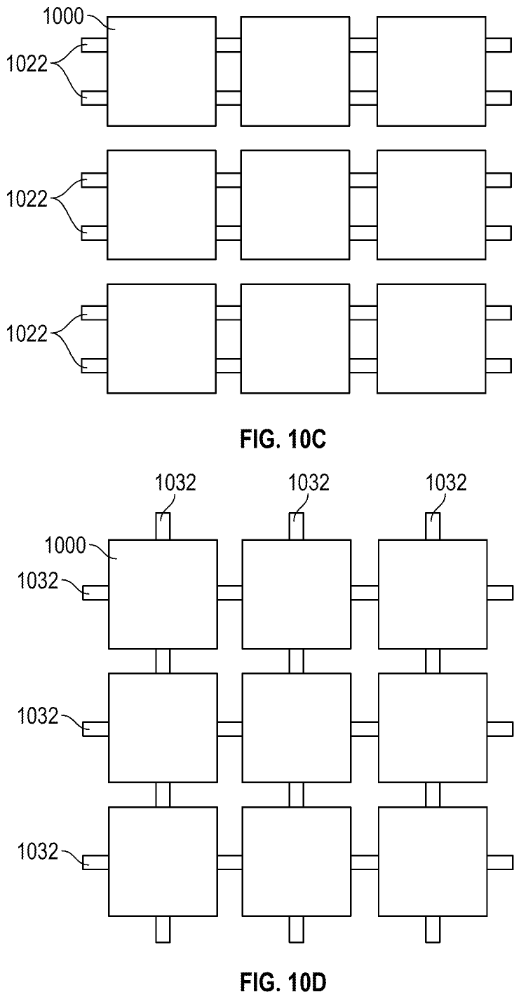

FIGS. 11A-11B illustrate an exemplary pixel 1100, according to embodiments of the disclosure. In some embodiments, a pixel is supported at two points via hinges, with each hinge anchored to a first via and attaching to the pixel using a second via. The hinge length may be reduced, and hinge cross-section area may be increased to increase torsional resistance around an axis. However, increasing torsional resistance may increase thermal conductance, which may not be desirable for pixels such as bolometer pixels.

In some embodiments, the pixel 1100 comprises a third point of support (in addition to the above-described two support points) to reduce the uniaxial rotational symmetry. In some embodiments, an additional hinge for creating the third point of support is not electrically conductive. Because in-plane stress (hinge is anchored at both ends in a fixed-fixed geometry) provides a contribution to bending resistance, it may be advantageous to incorporate such structures in the design of pixel suspension.

For example, FIG. 11A shows the pixel 1100 supported by hinge portions 1108, 1110, 1112, 1114, and 1116 at points 1102, 1104, and 1106. In some embodiments, hinge portions 1108, 1110, and 1112 belong to a first hinge, and hinge portions 1114 and 1116 belong to a second hinge. In some embodiments, the first hinge comprises a stressed and an unstressed portion, and the second hinge comprises a stressed and an unstressed portion. For example, the hinge portions 1108, 1110, 1112, and 1114 are tensile stressed, and the hinge portion 1116 is unstressed (e.g., behaving as fixed/free cantilevers), as allowed by symmetry. As another example, FIG. 11B shows the pixel 1100 supported by hinge portions 1128, 1130, 1132, 1134, and 1136 at points 1122, 1124, and 1126. In some embodiments, hinge portions 1128, 1130, and 1132 belong to a first hinge, and hinge portions 1134 and 1136 belong to a second hinge. As another example, the hinge portions 1128 and 1136 are tensile stressed, and the hinge portions 1130, 1132, and 1134 are unstressed. In some embodiments, the first hinge or the second hinge comprises a stressed hinge (not illustrated). In some embodiments, the first hinge or the second hinge comprises an un-stressed hinge (not illustrated).

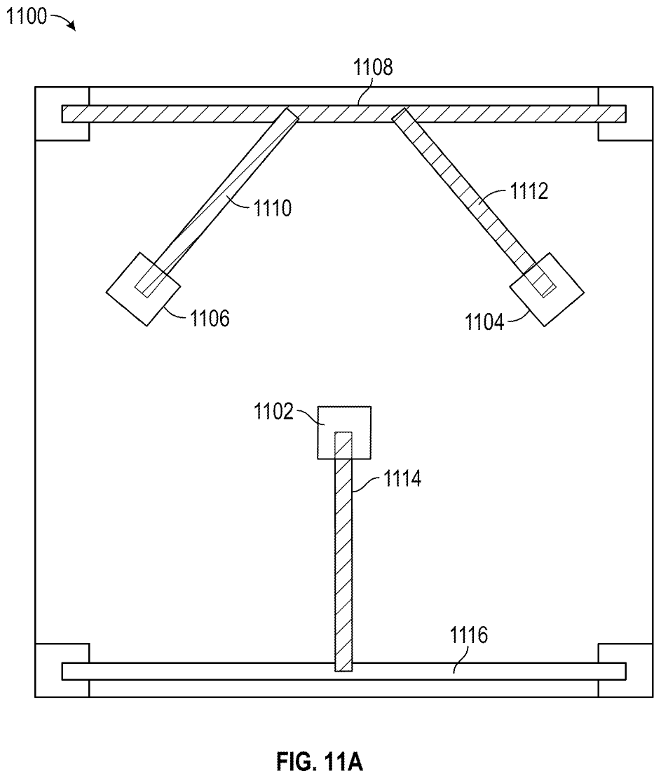

FIGS. 12A-12B illustrate exemplary pixels, according to embodiments of the disclosure. In some embodiments, design of a metal layer pattern may reduce electrostatic torque on the pixel. For example, the metal layers comprise EL in a sensor layer providing metal contacts for the sensor (e.g., sensor 702), HG in a hinge layer providing an electrically conductive path to connect to a first via and a second via, and M3 is a top layer on a substrate (e.g., top layer of a glass substrate). In some embodiments, the EL layer comprises a plate electrode of a pixel, and the M3 layer comprises a bottom electrode of a pixel.

In some embodiments, as described herein, a voltage may be applied across a pixel (e.g., a difference between a bias voltage and column line voltage) to generate a current. To reduce the electrostatic attraction between portions of the pixel that are different voltages, the various conductive layers at each voltage may be stacked vertically with little or no overlap with the conductive layers of the other voltage. For example, as illustrated in FIGS. 12A-12B, a first node and a second node (e.g., each node associated with a terminal of the pixel) of the pixel are disposed on different layers, and an area of overlap between the first node and the second node is less than threshold area (e.g., less than half of an area, less than a quarter of an area) of the first node or half an area of the second node. As illustrated in FIG. 12B, the exemplary pixel design allows a separation between a first voltage applied to a first area 1202 of the pixel and a second voltage applied to a second area 1204 of pixel, reducing effects of electrostatic forces on the pixel.

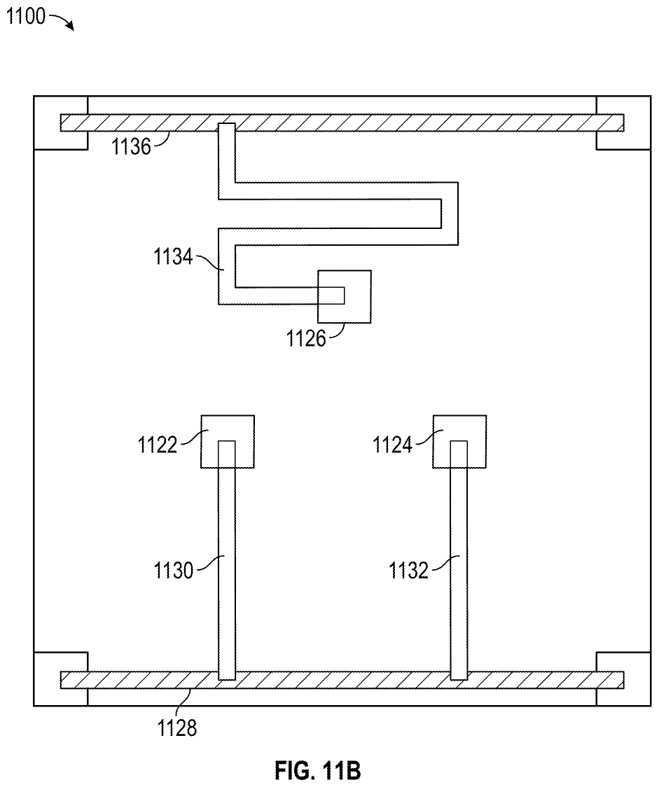

FIG. 13 illustrates an exemplary method 1300 of manufacturing an electronic device, according to embodiments of the disclosure. In some embodiments, the method 1300 is performed to manufacture a disclosed electronic device (e.g., electronic device 100, electronic device 200, electronic device 300, electronic device 800) or a component of the electronic device (e.g., hinges of the electronic device, pixels of the electronic device). For the sake of brevity, some features, material, dimensions, and advantages associated with these devices or components are not repeated here. Although the method 1300 is illustrated as including the described steps, it should be appreciated that different orders of steps, additional steps (e.g., combination with other methods disclosed herein), or fewer steps may be included without departing from the scope of the disclosure. For example, steps of method 1300 may be performed with steps of method 1400 and/or 1500.

In some embodiments, the method 1300 comprises providing a substrate (step 1302). For example, as described with respect to FIG. 1, a substrate 120 is provided. In some embodiments, the substrate is a glass substrate.

In some embodiments, the method 1300 comprises providing a first pixel and a second pixel (step 1304). In some embodiments, providing a first pixel and a second pixel comprises an array of pixels. For example, as described with respect to FIG. 1, a plurality of pixels (e.g., pixels 102A-102I) are provided. As another example, as described with respect to FIG. 2, a plurality of pixels (e.g., 202A-202T) are provided.

In some embodiments, the method 1300 comprises providing a first hinge and a second hinge. For example, as described with respect to FIGS. 1-3B, 6A-6C, a first hinge (e.g., hinges 104A-104I, hinges 204A-204T, hinges 304, hinges 606) and a second hinge (a second of e.g., hinges 104A-104I, hinges 204A-204T, hinges 304, hinges 606) are provided.

In some embodiments, the method 1300 comprises coupling the hinge to the substrate. For example, as described with respect to FIGS. 1-3B, 6A-6C, a hinge (e.g., hinges 104A-104I, hinges 204A-204T, hinges 304, hinges 606), is coupled to a substrate (e.g., substrate 120, substrate comprising backplane 310).

In some embodiments, the method 1300 comprises coupling the first pixel to the first hinge. For example, as described with respect to FIGS. 1-3B, 6A-6C, a first hinge (e.g., hinges 104A-104I, hinges 204A-204T, hinges 304, hinge 606, hinge 616, hinge 626) is electrically coupled to a first pixel (e.g., pixels 102A-102I, pixels 202A-202T, pixels 302, pixels 600).

In some embodiments, the method 1300 comprises coupling the second pixel to the second hinge. For example, as described with respect to FIGS. 1-3B, 6A-6C, a second hinge (a second of e.g., hinges 104A-104I, hinges 204A-204T, hinges 304, hinge 606, hinge 616, hinge 626) is electrically coupled to a second pixel (a second of e.g., pixels 102A-102I, pixels 202A-202T, pixels 302, pixels 600).

In some embodiments, the coupled first pixel and the coupled second pixel are separated by a pixel pitch. A length of the first hinge is greater than the pixel pitch, and a length of the second hinge is greater than the pixel pitch. For example, as described with respect to FIG. 2, a length of a hinge (e.g., hinges 204A-204T) is greater than a pixel pitch.

In some embodiments, the method 1300 further comprises forming a bias line on the glass substrate and electrically coupling the first pixel and the second pixel to a bias line. The first pixel is associated with a first row, and the second pixel is associated with a second row. For example, as described with respect to FIG. 2, two rows of pixels share a bias line.

In some embodiments, the method 1300 further comprises providing a bias-generating pixel. The bias-generating pixel is configured to generate a voltage of the bias line. For example, as described with respect to FIGS. 4 and 5, a bias-generating pixel (e.g., bias-generating pixels 404AA-404AM, 502A, 504A, 506A) is provided to generate a bias voltage (to be provided to a bias line).

In some embodiments, the method 1300 further comprises providing dummy pixels surrounding the bias-generating pixel. For example, as described with respect to FIGS. 4 and 5, a bias-generating pixel is surrounded by dummy pixels (e.g., to reduce edge effects on the bias-generating pixel).

In some embodiments, the method 1300 further comprises providing a second bias-generating pixel. The voltage of the bias line is generated based on an average voltage of the first bias-generating pixel and the second bias-generating pixel. For example, as described with respect to FIGS. 4 and 5, a second bias-generating pixel is provided (e.g., pixels 404A-404NM, pixel 502N, pixel 504N, pixel 506N) to generate a voltage, and the bias voltage is generated based on the average between a voltage generated by the first bias-generating pixel and a voltage generated by the second bias-generating pixel. In some embodiments, an area of the second bias-generating pixel is greater than an area of the first pixel and an area of the second pixel. For example, bias-generating pixel 502A is greater than an area of an active pixel, as described with respect to FIGS. 1-3B).

In some embodiments, the method 1300 further comprises providing a second bias-generating pixel. The voltage of the bias line is further generated via the second bias-generating pixel, and the area of the first bias-generating pixel is greater than an area of the second bias-generating pixel. For example, as described with respect to FIG. 5, an additional bias-generating pixel 504A or 506A is provided to further generating a bias voltage for the electronic device.

In some embodiments, the method 1300 further comprises providing a rivet and coupling the rivet to the first hinge or the second hinge. For example, as described with respect to FIGS. 6B and 6C, a rivet 620 is provided and coupled to hinge 616 or hinge 626.

In some embodiments, each of the first pixel and the second pixel comprises a sensor and an absorber. For example, as described with respect to FIG. 7A, the pixel 700 comprises a sensor and an absorber. In some embodiments, a first edge and a second edge of the absorber subtend an angle greater than 90 degrees. For example, as described with respect to FIG. 2, a pixel (e.g., pixel 202A-202T) comprises an absorber having a first edge and a second edge that subtend an angle greater than 90 degrees (e.g., as illustrated, the absorber has a parallelogram shape).

In some embodiments, the absorber comprises a contact. For example, as described with respect to FIG. 7A, the absorber 708 comprises a contact. In some embodiments, the sensor comprises a semiconductor layer between two dielectric layers. For example, as described with to FIG. 7A, the sensor 702 comprises a semiconductor layer, and the semiconductor layer is between insulating layers 704 and 706.

In some embodiments, the method 1300 further comprises providing a hinge layer and providing a sensor-absorber layer. The hinge layer comprises the first hinge and the second hinge, and the sensor-absorber layer comprises the two pixels. For example, a hinge (a second of e.g., hinges 104A-104I, hinges 204A-204T, hinges 304, hinge 606, hinge 616, hinge 626) belongs to a hinge layer, and a pixel (a second of e.g., pixels 102A-102I, pixels 202A-202T, pixels 302, pixels 600) belongs to a sensor-absorber layer.

In some embodiments, each of the first hinge and the second hinge comprises a conductive layer electrically coupled to the one of pixels and a dielectric layer disposed on a side of the conductive layer. For example, as described with respect to FIG. 6B, the hinge 616 comprise a SiNx layer 612 on a side of the TiNx layer 610. As another example, as described with respect to FIG. 6C, the hinge 626 comprise SiNx layers 612 and 614 on sides of the TiNx layer 610.

In some embodiments, a resistance of each of the first pixel and second pixel is between 100 kiloOhms and 10 megaOhms (e.g., as described with respect to FIGS. 1-3B and 6A-7B), and a resistance of each of the first hinge and the second hinge is between 10 kiloOhms and 100 kiloOhms (e.g., as described with respect to FIGS. 1-3B and 6A-7B).

In some embodiments, a gap between the one of the two pixels and the glass substrate is between 500 and 3000 nm, and each of the first pixel and second pixel is configured to absorb at least 35% of waves of incoming radiation having wavelengths between 6000 and 14000 nm. For example, as described with respect to FIGS. 7A and 7B, the pixel 700 is configured to absorb at least 35% of waves of incoming radiation having wavelengths between 6000 and 14000 nm.

In some embodiments, the method 1300 further comprises providing a readout circuit. The readout circuit is configured to measure a current from the first pixel or the second pixel. For example, as described with respect to FIG. 1, a readout circuit 110 is provided. In some embodiments, the method 1300 further comprises mounting the readout circuit on the glass substrate. For example, as described with respect to FIG. 1, a readout circuit 110 is mounted on substrate 120, and substrate 120 is a glass substrate

In some embodiments, the method 1300 further comprises mounting the readout circuit on a flexible circuit and coupling the flexible circuit to the glass substrate. For example, as described with respect to FIG. 1, a readout circuit 110 is mounted via a COF process. In some embodiments, the method 1300 further comprises providing a metal layer between the readout circuit and the glass substrate. For example, as described with respect to FIG. 1, a metal layer is provided between the readout circuit 100 and the substrate 120, which is a glass substrate.

In some embodiments, the method 1300 further comprises providing a multiplexer and electrically coupling the multiplexer to a testing circuit. For example, as described with respect to FIG. 8, a multiplexer 802 is provided to the electronic device 800, and the multiplexer 802 is configured to electrically couple to a testing circuit.

In some embodiments, a shape of the first pixel or the second pixel is convex. For example, as described with respect to FIG. 9, the pixel 900 comprises a convex shape. In some embodiments, the method 1300 further comprises providing a bridge for supporting the first pixel and second pixel. The bridge is between (1) the first and second pixels and (2) the substrate. Examples of the bridge are described with respect to FIGS. 10A-10D. In some embodiments, each of the first hinge and the second hinge comprises a stressed portion and an unstressed portion. Examples of a hinge comprising a stressed portion and unstressed portion are described with respect to FIGS. 11A and 11B

In some embodiments, a first node and a second node of the one of the first pixel or the second pixel are disposed on different layers, and an area of overlap between the first node and the second node is less than half an area of the first node or half an area of the second node. For example, as described with respect to FIGS. 12A and 12B, the nodes of a pixel are associated with different layers, and an area of overlap between the nodes are less than a threshold (e.g., less than half an area of the first node or an area of the second node).

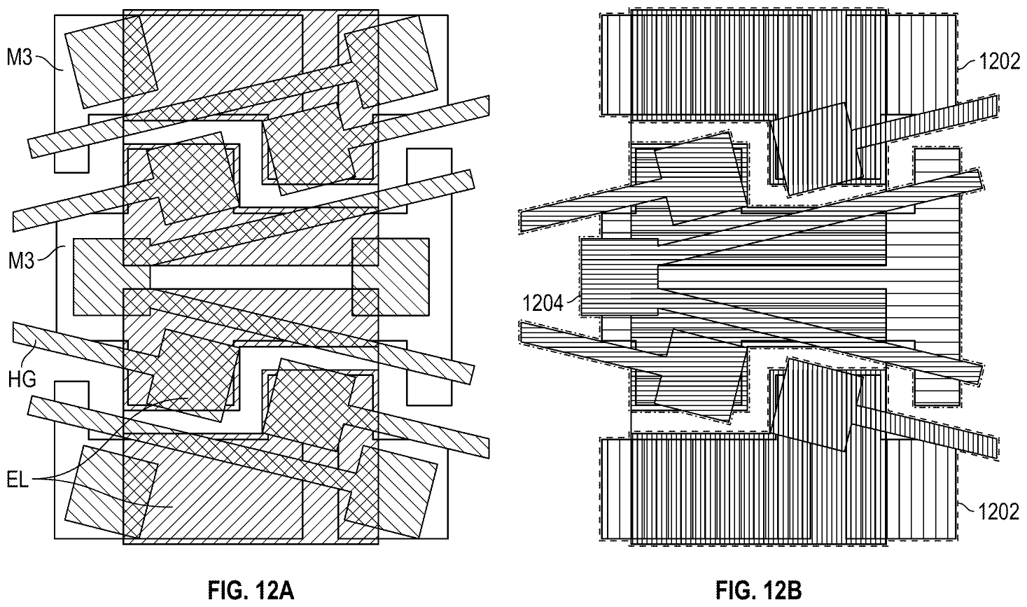

FIG. 14 illustrates an exemplary method 1400 of operating an electronic device, according to embodiments of the disclosure. In some embodiments, the method 1400 is performed to operate a disclosed electronic device (e.g., electronic device 100, electronic device 200, electronic device 300, electronic device 800) or a component of the electronic device (e.g., sensor circuit 400, sensor circuit 500). For the sake of brevity, some features and advantages associated with these devices or components are not repeated here. Although the method 1400 is illustrated as including the described steps, it should be appreciated that different orders of steps, additional steps (e.g., combination with other methods disclosed herein), or fewer steps may be included without departing from the scope of the disclosure. For example, steps of method 1300 may be performed with steps of method 1300 and/or 1500.

In some embodiments, the method 1400 comprises providing a first bias voltage, via a bias line, to a first pixel (step 1402). For example, as described with respect to FIG. 2, a first bias voltage is provided to via bias line 210A.

In some embodiments, the method 1400 further comprises generating the first bias voltage via a bias-generating pixel. For example, as described with respect to FIGS. 4 and 5, a bias-generating pixel (e.g., bias-generating pixels 404AA-404AM, 502A, 504A, 506A) is provided to generate a bias voltage (to be provided to a bias line).

In some embodiments, the method 1400 further comprises generating the first bias voltage further via a second bias-generating pixel. Generating the first bias voltage comprises averaging voltages generated by the first bias-generating pixel and the second bias-generating pixel. For example, as described with respect to FIGS. 4 and 5, a second bias-generating pixel is provided (e.g., pixels 404A-404NM, pixel 502N, pixel 504N, pixel 506N) to generate a voltage, and the bias voltage is generated based on the average between a voltage generated by the first bias-generating pixel and a voltage generated by the second bias-generating pixel. In some embodiments, an area of the second bias-generating pixel is greater than an area of the first pixel and an area of the second pixel. For example, bias-generating pixel 502A is greater than an area of an active pixel, as described with respect to FIGS. 1-3B).

In some embodiments, the method 1400 further comprises generating the first bias voltage further via a second bias-generating pixel. The area of the first bias-generating pixel is greater than an area of the second bias-generating pixel. For example, as described with respect to FIG. 5, an additional bias-generating pixel 504A or 506A is provided to further generating a bias voltage for the electronic device.

In some embodiments, the method 1400 comprises electrically coupling the first pixel to a column line (step 1404). For example, as described with respect to FIG. 2, pixel 202C is electrically coupled, via a switch 206C, to column line 212B.

In some embodiments, the method 1400 comprises electrically decoupling the first pixel from the column line (step 1406). For example, as described with respect to FIG. 2, pixel 202C is electrically decoupled, via the switch 206C, from column line 212B (e.g., after readout of row associated with row line 208A completes).

In some embodiments, the method 1400 comprises providing a second bias voltage, via the bias line, to a second pixel (step 1408). For example, as described with respect to FIG. 2, a second bias voltage is provided to via bias line 210A (to a different row of pixels described with respect to step 1402). In some embodiments, the second bias voltage is generated similarly as described above.

In some embodiments, the method 1400 comprises electrically coupling the second pixel to the column line (step 1410). For example, as described with respect to FIG. 2, pixel 202F is electrically coupled, via a switch 206H, to column line 212B.

In some embodiments, the method 1400 comprises electrically decoupling the second pixel from the column line (step 1406). For example, as described with respect to FIG. 2, pixel 202F is electrically decoupled, via the switch 206H, from column line 212B (e.g., after readout of row associated with row line 208B completes).

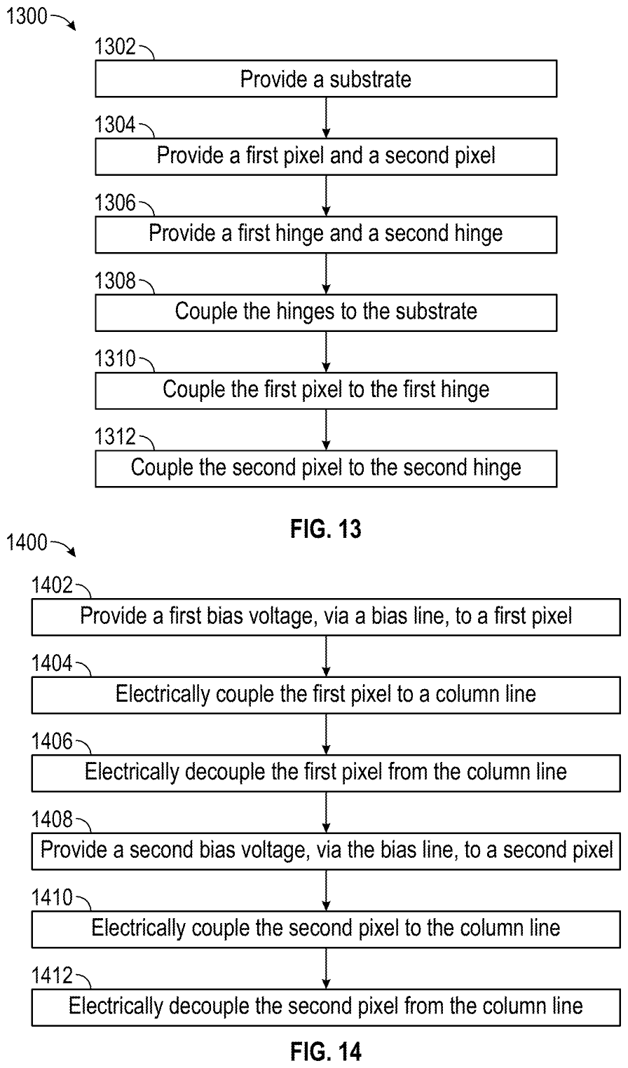

FIG. 15 illustrates a method 1500 of manufacturing an electromechanical system, in accordance with an embodiment. As non-limiting examples, the electrochemical system could be associated with the devices (e.g., electronic device 100, electronic device 200, electronic device 300, electronic device 800), components (e.g., a pixel described herein, a hinge described herein), or systems described herein. To manufacture an electromechanical system, all or some of the process steps in method 1500 could be used and used in a different order. As a non-limiting example, Step 1514 could be performed before Step 1512. In some embodiments, the method 1300 and/or method 1400 can be performed with method 1500.

Method 1500 includes Step 1502, providing a substrate. For example, the provided substrate comprises substrate 120. In some embodiments, the substrate is made of glass. In some embodiments, the substrate is low temperature polycrystalline silicon. In some embodiments, the substrate is a borosilicate that contains additional elements to fine tune properties. An example of a borosilicate is by Corning Eagle™, which produces an alkaline earth boro aluminosilicate (a silicate loaded with boron, aluminum, and various alkaline earth elements). Other variations are available from Asahi Glass™ or Schott™.

In some embodiments, a flat panel glass process is used to manufacture the electromechanical system. In some embodiments, a liquid crystal display (LCD) process is used to manufacture the electromechanical system. In some embodiments, an OLED display process or an x-ray panel process is used. Employing a flat panel glass process may allow for increased substrate sizes, thereby allowing for a higher number of electrochemical systems per substrate, which reduces processing costs. Substrate sizes for “Panel Level” can include 620 mm×750 mm, 680 mm×880 mm, 1100 mm×1300 mm, 1300 mm×1500 mm, 1500 mm×1850 mm, 1950 mm×2250 mm, and 2200 mm×2500 mm. Further, thin film transistors (TFTs) in panel level manufacturing can also reduce cost and so, for example, LCD-TFT processes can be beneficial.

Method 1500 includes Step 1504, adding MEMS (e.g., the disclosed MEMS sensors) to the substrate. Although MEMS is used to describe the addition of structures, it should be appreciated that other structures (e.g., NEMS, other kinds of devices) could be added without deviating from the scope of this disclosure. In embodiments using panel level processing, the MEMS structures may be added using an LCD-TFT process.

Step 1504 may be followed by optional Step 1516, sub-plating. Step 1516 may be used when the substrate is larger than the processing equipment used in subsequent steps. For example, if using a panel level process (such as LCD), some embodiments will include (at Step 1504) cutting the panel into wafer sizes to perform further processing (using, for example, CMOS manufacturing equipment). In other embodiments, the same size substrate is used throughout method 1500 (i.e., Step 1516 is not used).

Method 1500 includes Step 1506, releasing the MEMS from the substrate.

Method 1500 includes Step 1508, post-release processing. Such post-release processing may prepare the MEMS structure for further process steps, such as planarization. In wafer-level processing, planarization can include chemical mechanical planarization. In some embodiments, the further process steps include etch back, where a photoresist is spun onto the topography to generate a more planar surface, which is then etched. Higher control of the etch time can yield a smoother surface profile. In some embodiments, the further process steps include “spin on glass,” where glass-loaded organic binder is spun onto the topography and the result is baked to drive off organic solvents, leaving behind a surface that is smoother.

Method 1500 includes Step 1510, vacuum encapsulation of the MEMS structure, where necessary. Vacuum encapsulation may be beneficial to prolong device life.

Method 1500 includes Step 1512, singulation. Some embodiments may include calibration and chip programming, which may take into account the properties of the sensors. Methods described herein may be advantageous in glass substrate manufacturing processes because uniformity in glass lithography capabilities is limited. As a further advantage, glass has a lower thermal conductivity and so a glass substrate can be a better thermal insulator; by manufacturing thin structures separating a bolometer pixel from a glass substrate, embodiments herein may better serve to thermally isolate the glass bolometer pixel from the packaging environment. In some embodiments, prior to singulation, properties of the MEMS are measured (for example, via multiplexer 802).

Method 1500 includes Step 1514, attachment of a readout integrated circuit (ROIC) and flex/PCB attachment. As non-limiting examples, the readout circuits (e.g., readout circuit 110) could be associated with devices or systems described herein. Processes and devices described herein may have the further advantage that the area required for signal processing can be much smaller than the sensing area which is dictated by the sensing physics. Typically, sensors are integrated on top of CMOS circuitry, and area driven costs lead to a technology node that is not optimal for the signal processing task. Processes described herein can use a more suitable CMOS and drive down the area required for signal processing, freeing the sensor from any area constraints by leveraging the low cost of FPD (flat panel display) manufacturing. In some embodiments, the ROIC is specifically designed for sensing a specific electromagnetic wavelength (such as X-Rays, THz, LWIR).

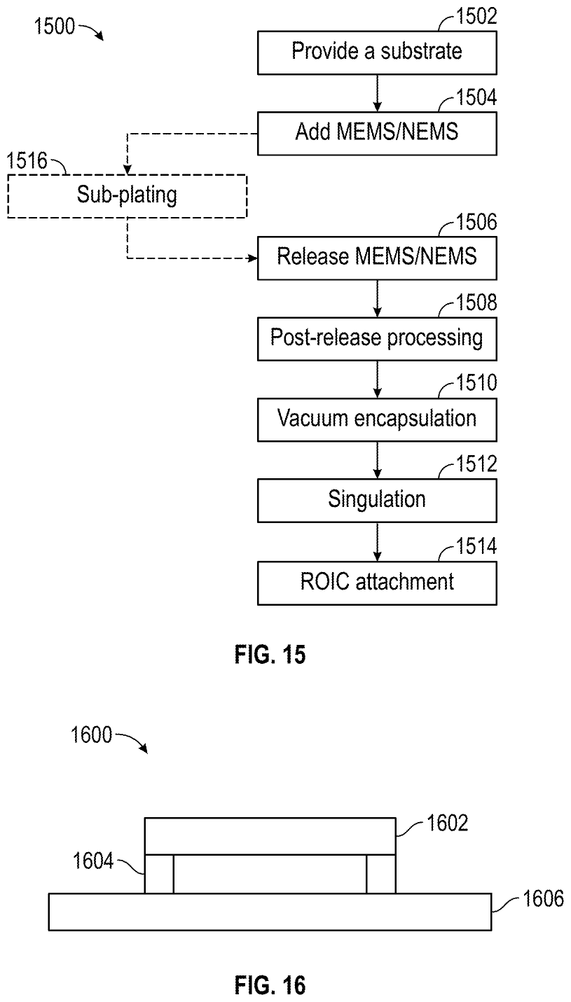

FIG. 16 illustrates an exemplary sensor. In some embodiments, sensor 1600 is manufactured using steps of method 1400 and/or method 1500. Sensor 1600 includes glass substrate 1606, structure 1604 (e.g., less than 250 nm wide) coupled to glass substrate 1606, and a pixel 1602 coupled to the structure 1604. In some embodiments, the substrate 1606 comprises substrate 120. In some embodiments, the pixel 1602 comprises a pixel described herein. In some embodiments of sensor 1600, structure 1604 is a hinge (e.g., a hinge described herein) that thermally separates the active area from the glass. In some embodiments, sensor 1600 experiences a voltage difference and generates an current or charge based on the received radiation (e.g., the resistance between two terminals of the sensor changes in response to exposure to LWIR radiation).

In some embodiments, a sensor includes a glass substrate, a structure manufactured from any of the methods described herein and coupled to the glass substrate, and a pixel coupled to the structure.

In some embodiments, a sensor includes a MEMS or NEMS device manufactured by a LCD-TFT manufacturing process and a structure manufactured by any of the methods described herein.

By way of examples, sensors can include resistive sensors and capacitive sensors. Bolometers can be used in a variety of applications. For example, long wave infra-red (LWIR, wavelength of approximately 8-12 μ m) bolometers can be used in the automotive and commercial security industries. For example, LWIR bolometers with QVGA, VGA, and other resolution. Terahertz (THz, wavelength of approximately 1.0-0.1 mm) bolometers can be used in security (e.g., airport passenger security screening) and medical (medical imaging). For example, THz bolometers with QVGA resolution and other resolutions. Some electrochemical systems can include X-Ray sensors or camera systems. Similarly, LWIR and THz sensors are used in camera systems. Some electromechanical systems are applied in medical imaging, such as endoscopes and exoscopes. X-ray sensors include direct and indirect sensing configurations.

Other electromechanical systems include scanners for light detection and ranging (LIDAR) systems. For example, optical scanners where spatial properties of a laser beam could be shaped (for, e.g., beam pointing). Electromechanical systems include inertial sensors (e.g., where the input stimulus is linear or angular motion). Some systems may be used in bio sensing and bio therapeutic platforms (e.g., where biochemical agents are detected).

In some embodiments, a non-transitory computer readable storage medium stores one or more programs, and the one or more programs includes instructions. When the instructions are executed by an electronic device (e.g., electronic device 100, electronic device 200, electronic device 300, electronic device 800) with one or more processors and memory, the instructions cause the electronic device to perform the methods described with respect to e.g., FIGS. 1, 2, 4, 5, and 8.

In some embodiments, an electronic device, comprises a glass substrate; two pixels comprising a pixel pitch; and a hinge between one of the two pixels and the glass substrate. The hinge supports the pixel; and a length of the hinge is greater than the pixel pitch.

In some embodiments, the electronic device further comprises a bias line. The two pixels are electrically coupled to the bias line, the one of the two pixels is associated with a first row, and the other of the two pixel is associated with a second row.

In some embodiments, a voltage of the bias line is generated via a bias-generating pixel.

In some embodiments, the electronic device further comprises dummy pixels surrounding the bias-generating pixel.

In some embodiments, the electronic device further comprises a second bias-generating pixel, wherein the voltage of the bias line is generated based on an average voltage of the first bias-generating pixel and the second bias-generating pixel.

In some embodiments, an area of the bias-generating pixel is greater than an area of the one of the two pixels.

In some embodiments, the electronic device further comprises a second bias-generating pixel. The voltage of the bias line is further generated via the second bias-generating pixel, and the area of the first bias-generating pixel is greater than an area of the second bias-generating pixel.

In some embodiments, the electronic device further comprises a rivet coupled to the hinge.

In some embodiments, the one of the two pixels comprises a sensor and an absorber.

In some embodiments, a first edge and a second edge of the absorber subtend an angle greater than 90 degrees.

In some embodiments, the electronic device further comprises a hinge layer and a sensor-absorber layer. The hinge layer comprises the hinge, and the sensor-absorber layer comprises the two pixels.

In some embodiments, the absorber comprises a contact.

In some embodiments, the sensor comprises a semiconductor layer between two dielectric layers.

In some embodiments, a gap between the one of the two pixels and the glass substrate is between 500 and 3000 nm, and the one of the two pixels is configured to absorb at least 35% of waves of incoming radiation having wavelengths between 6000 and 14000 nm.

In some embodiments, the electronic device further comprises a readout circuit configured to measure a current from the one of the two pixels.

In some embodiments, the readout circuit is mounted on the glass substrate.

In some embodiments, the readout circuit is mounted on a flexible circuit coupled to the glass substrate.

In some embodiments, the electronic device further comprises a metal layer between the readout circuit and the glass substrate.

In some embodiments, the electronic device further comprises a multiplexer configured to electrically couple to a testing circuit.

In some embodiments, a resistance of the one of the two pixels is between 100 kiloOhms and 10 megaOhms, and a resistance of the hinge is between 10 kiloOhms and 100 kiloOhms.

In some embodiments, the hinge comprises a conductive layer electrically coupled to the one of pixels and a dielectric layer disposed on a side of the conductive layer.

In some embodiments, a shape of the one of the two pixels is convex.

In some embodiments, the two pixels are adjacent pixels, and the electronic device further comprises a bridge for supporting the two pixels, wherein the bridge is between the two pixels and the substrate.

In some embodiments, the hinge comprises a stressed portion and an unstressed portion.

In some embodiments, a first node and a second node of the one of the two pixels are disposed on different layers, and an area of overlap between the first node and the second node is less than half an area of the first node or half an area of the second node.

In some embodiments, a method for manufacturing an electronic device comprises: providing a glass substrate; providing a first pixel and a second pixel; providing a first hinge and a second hinge; coupling the first hinge and the second hinge to the glass substrate; coupling the first pixel to the first hinge; and coupling the second pixel to the second hinge. The coupled first pixel and the coupled second pixel are separated by a pixel pitch, a length of the first hinge is greater than the pixel pitch, and a length of the second hinge is greater than the pixel pitch.

In some embodiments, the method further comprises: forming a bias line on the glass substrate; and electrically coupling the first pixel and the second pixel to a bias line. The first pixel is associated with a first row, and the second pixel is associated with a second row.

In some embodiments, the method further comprises providing a bias-generating pixel, wherein the bias-generating pixel is configured to generate a voltage of the bias line.

In some embodiments, the method further comprises providing dummy pixels surrounding the bias-generating pixel.

In some embodiments, the method further comprises providing a second bias-generating pixel, wherein the voltage of the bias line is generated based on an average voltage of the first bias-generating pixel and the second bias-generating pixel.

In some embodiments, an area of the bias-generating pixel is greater than an area of the first pixel and an area of the second pixel.

In some embodiments, the method further comprises providing a second bias-generating pixel. The voltage of the bias line is further generated via the second bias-generating pixel, and the area of the first bias-generating pixel is greater than an area of the second bias-generating pixel.

In some embodiments, the method further comprises: providing a rivet, and coupling the rivet to the first hinge or the second hinge.

In some embodiments, each of the first pixel and second pixel comprises a sensor and an absorber.

In some embodiments, a first edge and a second edge of the absorber subtend an angle greater than 90 degrees.

In some embodiments, the method further comprises: providing a hinge layer; and providing a sensor-absorber layer. The hinge layer comprises the first hinge and the second hinge, and the sensor-absorber layer comprises the two pixels.

In some embodiments, the absorber comprises a contact.

In some embodiments the sensor comprises a semiconductor layer between two dielectric layers.

In some embodiments, a gap between the one of the two pixels and the glass substrate is between 500 and 3000 nm, and each of the first pixel and second pixel is configured to absorb at least 35% of waves of incoming radiation having wavelengths between 6000 and 14000 nm.

In some embodiments, the method further comprises: providing a readout circuit. The readout circuit is configured to measure a current from the first pixel or the second pixel.

In some embodiments, the method further comprises mounting the readout circuit on the glass substrate.

In some embodiments, the method further comprising mounting the readout circuit on a flexible circuit; and coupling the flexible circuit to the glass substrate.

In some embodiments, the method further comprises providing a metal layer between the readout circuit and the glass substrate.

In some embodiments, the method further comprises providing a multiplexer and electrically coupling the multiplexer to a testing circuit.

In some embodiments, the method of claim 28, a resistance of each of the first pixel and second pixel is between 100 kiloOhms and 10 megaOhms, and a resistance of each of the first hinge and the second hinge is between 10 kiloOhms and 100 kiloOhms.

In some embodiments, wherein each of the first hinge and the second hinge comprises a conductive layer electrically coupled to the one of pixels and a dielectric layer disposed on a side of the conductive layer.

In some embodiments, a shape of the first pixel or the second pixel is convex.

In some embodiments, the method further comprises providing a bridge for supporting the first pixel and second pixel, wherein the bridge is between (1) the first and second pixels and (2) the substrate.

In some embodiments, each of the first hinge and the second hinge comprises a stressed portion and an unstressed portion.

In some embodiments, a first node and a second node of the one of the first pixel or the second pixel are disposed on different layers, and an area of overlap between the first node and the second node is less than half an area of the first node or half an area of the second node.

In some embodiments, an electronic device comprises: an array of pixels comprising: a first pixel belonging to a first row of the array and a column of the array; and a second pixel belonging to a second row of the array and the column of the array; a bias line electrically coupled to the first pixel and the second pixel; and a column line associated with the column of the array. And a method for operating the electronic device comprises: providing a first bias voltage, via the bias line, to the first pixel; electrically coupling the first pixel to the column line; electrically decoupling the first pixel from the column line; providing a second bias voltage, via the bias line, to the second pixel; electrically coupling the second pixel to the column line; and electrically decoupling the second pixel from the column line.

In some embodiments, the method further comprises generating the first bias voltage via a bias-generating pixel.

In some embodiments, the method further comprises generating the first bias voltage further via a second bias-generating pixel, wherein generating the first bias voltage comprises averaging voltages generated by the first bias-generating pixel and the second bias-generating pixel.

In some embodiments, an area of the bias-generating pixel is greater than an area of the first pixel and an area of the second pixel.

In some embodiments, the method further comprises generating the first bias voltage further via a second bias-generating pixel, wherein the area of the first bias-generating pixel is greater than an area of the second bias-generating pixel.

Although “electrically coupled” and “coupled” are used to describe the electrical connections between two electronic components or elements in this disclosure, it is understood that the electrical connections do not necessarily need direct connection between the terminals of the components or elements being coupled together. For example, electrical routing connects between the terminals of the components or elements being electrically coupled together. In another example, a closed (conducting or an “on”) switch is connected between the terminals of the components being coupled together. In yet another example, additional elements connect between the terminals of the components being coupled together without affecting the characteristics of the circuit. For example, buffers, amplifiers, and passive circuit elements can be added between components or elements being coupled together without affecting the characteristics of the disclosed circuits and departing from the scope of this disclosure.

Those skilled in the art will recognize that the systems described herein are representative, and deviations from the explicitly disclosed embodiments are within the scope of the disclosure. For example, some embodiments include additional sensors or cameras, such as cameras covering other parts of the electromagnetic spectrum, can be devised using the same principles.

Although the disclosed embodiments have been fully described with reference to the accompanying drawings, it is to be noted that various changes and modifications will become apparent to those skilled in the art. Such changes and modifications are to be understood as being included within the scope of the disclosed embodiments as defined by the appended claims.

The terminology used in the description of the various described embodiments herein is for the purpose of describing particular embodiments only and is not intended to be limiting. As used in the description of the various described embodiments and the appended

We claim:

1. An electronic device, comprising:
a glass substrate;
two pixels comprising a pixel pitch; and
a hinge between one of the two pixels and the glass substrate, wherein:
the hinge supports the pixel, and
a length of the hinge is greater than the pixel pitch.

2. The electronic device of claim 1, further comprising a bias line, wherein:
the two pixels are electrically coupled to the bias line,
the one of the two pixels is associated with a first row, and
the other of the two pixel is associated with a second row.

3. The electronic device of claim 2, wherein a voltage of the bias line is generated via a bias-generating pixel.

4. The electronic device of claim 3, further comprising a second bias-generating pixel, wherein the voltage of the bias line is generated based on an average voltage of the first bias-generating pixel and the second bias-generating pixel.

5. The electronic device of claim 3, wherein an area of the bias-generating pixel is greater than an area of the one of the two pixels.

6. The electronic device of claim 1, further comprising a rivet coupled to the hinge.

7. The electronic device of claim 1, wherein the one of the two pixels comprises a sensor and an absorber.

8. The electronic device of claim 7, wherein a first edge and a second edge of the absorber subtend an angle greater than 90 degrees.

9. The electronic device of claim 1, wherein:
a gap between the one of the two pixels and the glass substrate is between 500 and 3000 nm, and
the one of the two pixels is configured to absorb at least 35% of waves of incoming radiation having wavelengths between 6000 and 14000 nm.

10. The electronic device of claim 1, wherein:
a resistance of the one of the two pixels is between 100 kiloOhms and 10 megaOhms, and
a resistance of the hinge is between 10 kiloOhms and 100 kiloOhms.

11. The electronic device of claim 1, wherein the hinge comprises a conductive layer electrically coupled to the one of pixels and a dielectric layer disposed on a side of the conductive layer.

12. The electronic device of claim 1, wherein a shape of the one of the two pixels is convex.

13. The electronic device of claim 1, wherein:
the two pixels are adjacent pixels, and
the electronic device further comprises a bridge for supporting the two pixels, wherein the bridge is between the two pixels and the substrate.

14. The electronic device of claim 1, wherein the hinge comprises a stressed portion and an unstressed portion.

15. The electronic device of claim 1, wherein:
a first node and a second node of the one of the two pixels are disposed on different layers, and
an area of overlap between the first node and the second node is less than half an area of the first node or half an area of the second node.

16. A method for manufacturing an electronic device, comprising:
providing a glass substrate;
providing a first pixel and a second pixel;
providing a first hinge and a second hinge;
coupling the first hinge and the second hinge to the glass substrate;
coupling the first pixel to the first hinge; and
coupling the second pixel to the second hinge, wherein:
the coupled first pixel and the coupled second pixel are separated by a pixel pitch,
a length of the first hinge is greater than the pixel pitch, and
a length of the second hinge is greater than the pixel pitch.

17. A method for operating an electronic device comprising:
an array of pixels comprising:
a first pixel belonging to a first row of the array and a column of the array; and
a second pixel belonging to a second row of the array and the column of the array;
a bias line electrically coupled to the first pixel and the second pixel; and
a column line associated with the column of the array,
wherein the method comprises:
providing a first bias voltage, via the bias line, to the first pixel;
electrically coupling the first pixel to the column line;
electrically decoupling the first pixel from the column line;
providing a second bias voltage, via the bias line, to the second pixel;
electrically coupling the second pixel to the column line; and
electrically decoupling the second pixel from the column line.
